(19) United States
(12) Patent Application Publication
(10) Pub. No.: US 2017/0338238 A1
(43) Pub. Date: Nov. 23, 2017

(54) SEMICONDUCTOR DEVICE

(71) Applicant: GANG ZHANG, Suwon-si (KR)

(72) Inventor: GANG ZHANG, Suwon-si (KR)

(21) Appl. No.: 15/436,759

(22) Filed: Feb. 17, 2017

(30) Foreign Application Priority Data
May 20, 2016 (KR) 10-2016-0062384

(51) Int. Cl. H01L 27/11578; H01L 27/11551; H01L 27/11519; H01L 27/11565; H01L 29/08; H01L 29/10; H01L 29/423

(52) U.S. Cl. CPC H01L 27/11578; H01L 29/0847; H01L 27/11551; H01L 29/1037; H01L 27/11519; H01L 27/11565; H01L 29/42332; H01L 29/42348

(57) ABSTRACT

A semiconductor device is provided. The semiconductor device includes an electrode structure that has gate electrodes that are sequentially stacked on a semiconductor layer, vertical structures that penetrate the electrode structure, and horizontal structures that extend in a third direction below the electrode structure. The vertical structures extend in a first direction and are spaced apart from each other in a second direction that crosses the first direction. Each of the vertical structures includes vertical channel patterns arranged in the first direction. The horizontal structure includes horizontal channel patterns. Each of the horizontal channel patterns is connected to at least three of the vertical channel patterns.

### CROSS-REFERENCE TO RELATED APPLICATIONS

This U.S. nonprovisional patent application claims priority under 35 U.S.C. §119 of Korean Patent Application 10-2016-0062384 filed on May 20, 2016, the entire contents of which are hereby incorporated by reference.

### BACKGROUND

The present inventive concept relates to a semiconductor device and, more particularly, to a vertical semiconductor memory device.

In order to satisfy high-performance and low manufacturing-cost requirements, the integration of semiconductor devices, such as semiconductor memory devices, needs to increase. In this regard, the degree of integration of a semiconductor device provides a critical factor in determining the price of the semiconductor device. The degree of integration of, for example, two-dimensional semiconductor memory devices is primarily determined by the area occupied by a unit memory cell, and is greatly influenced by the level of technology used to form fine patterns. The expense associated with the processing equipment used to increase pattern fineness, however, sets a practical limitation on increasing the integration of two-dimensional semiconductor memory devices.

### SUMMARY

Embodiments of the present inventive concept provide a semiconductor device that can be manufactured by a simple process and has increased integration and reliability.

According to exemplary embodiments of the present inventive concept, a semiconductor device may comprise: an electrode structure that includes gate electrodes that are sequentially stacked on a semiconductor layer; vertical structures that penetrate the electrode structure, extend in a first direction, and are spaced apart from each other in a second direction that crosses the first direction, each of the vertical structures including vertical channel patterns that are arranged in the first direction; and horizontal structures that extend in a third direction that crosses the first direction below the electrode structure, the horizontal structures including horizontal channel patterns. Each of the horizontal channel patterns may be connected to at least three of the vertical channel patterns.

According to exemplary embodiments of the present inventive concept, a semiconductor device may comprise: an electrode structure that includes a plurality of gate electrodes that are sequentially provided on a semiconductor layer and extend in a first direction; and vertical structures that separate each of the plurality of gate electrodes in a second direction crossing the first direction, the vertical structures including data storage layers and channel patterns. The channel patterns may comprise: vertical channel patterns that are spaced apart from each other in the first direction across the data storage layers; and horizontal channel patterns that extend from the vertical channel patterns to below the electrode structure and connected to the vertical channel patterns of the vertical structures.

According to exemplary embodiments of the present inventive concept, a semiconductor device may comprises: a vertically stacked gate electrode structure that may include a plurality of levels in which each level may include a plurality of gate electrodes, each gate electrode may extend in a first direction and may be separated from an adjacent gate electrode in a second direction and from an adjacent gate electrode in a vertical direction and in which the second direction may be substantially perpendicular to the first direction, and the vertical direction may be substantially perpendicular to the first direction and the second direction; a plurality of vertical structures that may extend in a first direction and separate the gate electrodes in the second direction in which each of the vertical structures may include a plurality of vertical channel patterns that are arranged in the first direction; and a plurality of horizontal structures that may extend in a third direction in which the third direction may be substantially parallel to the first direction and the second direction, the third direction may be different from the first direction and different from the second direction, in which the horizontal structures may include horizontal channel patterns, and in which each of the horizontal channel patterns may be connected to at least three of the vertical channel patterns.

According to exemplary embodiments of the present inventive concept, a method to form a semiconductor device may include: forming a plurality of horizontal structures in which the horizontal structures may extend in a first direction; forming a vertically stacked gate electrode structure in a vertical direction above the plurality of horizontal structures in which the vertically stacked electrode structure may include a plurality of levels; forming a plurality of vertical structures that may penetrate the vertically stacked gate electrode structure in which the plurality of vertical structures may extend in a second direction and may separate the vertically stacked electrode structure in a third direction to form a plurality of gate electrodes that may be separated from each other in the third direction in which the third direction may be substantially perpendicular to the second direction, the vertical direction may be substantially perpendicular to the second direction and the third direction, the first direction being substantially parallel to the second direction and the third direction, and the first direction may be different from the second direction and different from the third direction, in which each of the vertical structures may include a plurality of vertical channel patterns that are arranged in the second direction; and in which at least three of the vertical channel patterns, each from a different vertical structure, may be connected to a horizontal channel pattern.

### BRIEF DESCRIPTION OF THE DRAWINGS

FIG. 1 depicts a block diagram of a semiconductor device according to exemplary embodiments of the present inventive concept.

FIG. 2 depicts a block diagram of an example of the memory cell array of FIG. 1.

FIG. 3A depicts a plan view of a semiconductor device according to exemplary embodiments of the present inventive concept.

FIG. 3B depicts a cross-sectional view taken along line I-I′ in FIG. 3A.

FIG. 3C depicts a cross-sectional view taken along line II-IP in FIG. 3A.

FIG. 4 depicts a circuit diagram of a cell array of a semiconductor device according to exemplary embodiments of the present inventive concept.

FIG. 5A depicts a circuit diagram of one memory block corresponding to section P in FIG. 4.

FIG. 5B depicts a diagram showing components of the circuit diagram of FIG. 5A that are connected to each gate electrode that differentiate the gate electrodes from each other.

FIGS. 6A to 13A respectively depict plan views for explaining a method for fabricating a semiconductor device according to exemplary embodiments of the present inventive concept.

FIGS. 6B to 13B respectively depict cross-sectional views taken along line I-I′ in FIGS. 6A to 13A.

FIGS. 6C to 13C respectively depict cross-sectional views taken along line II-IP in FIGS. 6A to 13A.

FIGS. 14A and 14B depict plan views for explaining vertical data storage layers according to exemplary embodiments of the present inventive concept.

FIG. 15 depicts a cross-sectional view, taken along line II-IP in FIG. 8A, for explaining a method for fabricating a semiconductor device according to exemplary embodiments of the present inventive concept.

FIG. 16 depicts a block diagram of a semiconductor device according to exemplary embodiments of the present inventive concept.

FIG. 17 depicts a block diagram of a semiconductor device according to exemplary embodiments of the present inventive concept.

FIGS. 18A and 18B depict plan views for explaining shapes of vertical holes.

### DETAILED DESCRIPTION OF EMBODIMENTS

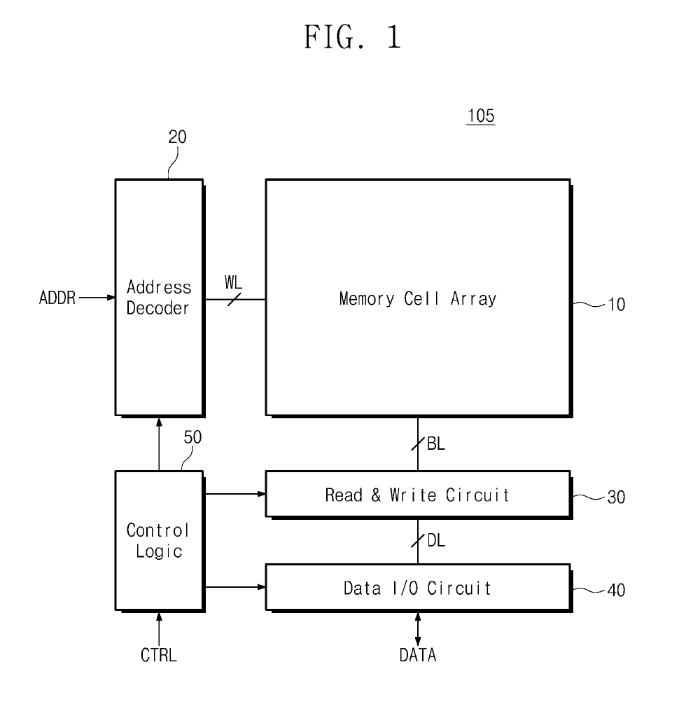

FIG. 1 depicts a block diagram of a semiconductor device according to exemplary embodiments of the present inventive concept. As used herein, the word “exemplary” means “serving as an example, instance, or illustration.” Any embodiment described herein as “exemplary” is not to be construed as necessarily preferred or advantageous over other embodiments. Referring to FIG. 1, a semiconductor device 105 according to exemplary embodiments of the present inventive concept may include a memory cell array 10, an address decoder 20, a read/write circuit 30, a data input/output (I/O) circuit 40, and a control logic 50.

The memory cell array 10 may include a plurality of memory cells. The memory cells of the memory cell array 10 may be configured to store one or more bits per cell. The memory cell array 10 may be connected to the address decoder 20 through a plurality of word lines WL and may be connected to the read/write circuit 30 through a plurality of bit lines BL.

The address decoder 20 may be connected to the memory cell array 10 through the word lines WL. The address decoder 20 may be configured to operate in response to the control of the control logic 50. The address decoder 20 may receive an address ADDR from a device that is external to the semiconductor device 105. The address decoder 20 may decode a row address among the received addresses ADDR and select a corresponding one or more of the plurality of word lines WL. Additionally, the address decoder 20 may decode a column address among the received addresses ADDR and transfer the decoded column address to the read/write circuit 30. For example, the address decoder 20 may include a row decoder, a column decoder, an address buffer, and the like (all not shown in FIG. 1).

The read/write circuit 30 may be connected to the memory cell array 10 through the bit lines BL, and may be connected to the data I/O circuit 40 through a plurality of data lines DL. The read/write circuit 30 may operate in response to the control of the control logic 50. The read/write circuit 30 may be configured to receive the decoded column address from the address decoder 20. The read/write circuit 30 may use the decoded column address to select one or more bit lines BL corresponding to the decoded column address. For example, the read/write circuit 30 may receive data from the data I/O circuit 40 and write the received data in the memory cell array 10. The read/write circuit 30 may read data from the memory cell array 10 and transfer the read data to the data I/O circuit 40. The read/write circuit 30 may read data from a first storage region of the memory cell array 10 and write the read data in a second storage region of the memory cell array 10. For example, the read/write circuit 30 may be configured to perform a copy-back operation.

The read/write circuit 30 may include components, such as a page buffer (or a page register) and a column select circuit (both not shown in FIG. 1). Alternatively, the read/write circuit 30 may include components, such as a sense amplifier, a write driver, and a column select circuit (all not shown in FIG. 1).

The data I/O circuit 40 may be connected to the read/write circuit 30 through the data lines DL. The data I/O circuit 40 may operate in response to the control of the control logic 50. The data I/O circuit 40 may be configured to exchange data DATA with a device that is external to the semiconductor device 105. The data I/O circuit 40 may be configured to receive data DATA from a device that is external to semiconductor device 105 and transfer the data DATA to the read/write circuit 30 through the data lines DL. The data I/O circuit 40 may be configured to receive data DATA through the data lines DL from the read/write circuit 30 and output the data DATA to a device that is external to the semiconductor device 105. For example, the data I/O circuit 40 may include a component, such as a data buffer (not shown in FIG. 1).

The control logic 50 may be connected to the address decoder 20, the read/write circuit 30, and the data I/O circuit 40. The control logic 50 may be configured to control one or more operations of the semiconductor device 105. The control logic 50 may operate in response to a control signal CTRL transmitted from an external device.

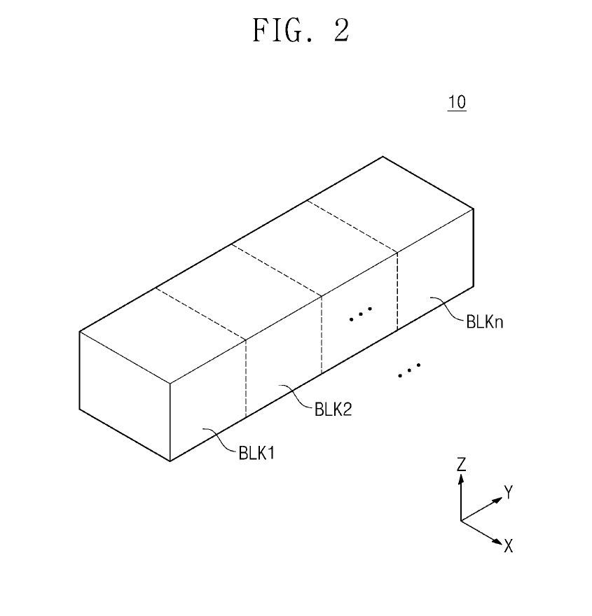

FIG. 2 depicts a block diagram of the example memory cell array 10 of FIG. 1. Referring to FIG. 2, the memory cell array 10 may include a plurality of memory blocks BLK1 to BLKn. Each memory block may have a three-dimensional (or a vertical) structure. For example, each memory block may include structures extending in first to third directions X, Y and Z. That is, each memory block may include three-dimensional (3D) structures. In particular—each memory block may include, for example, a plurality of cell strings that extend in the third direction Z.

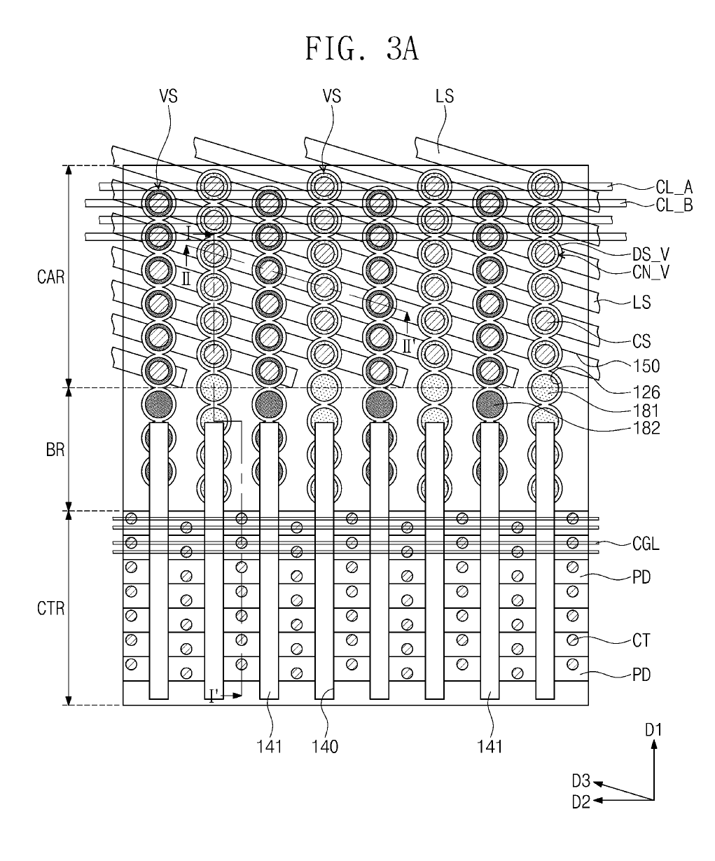

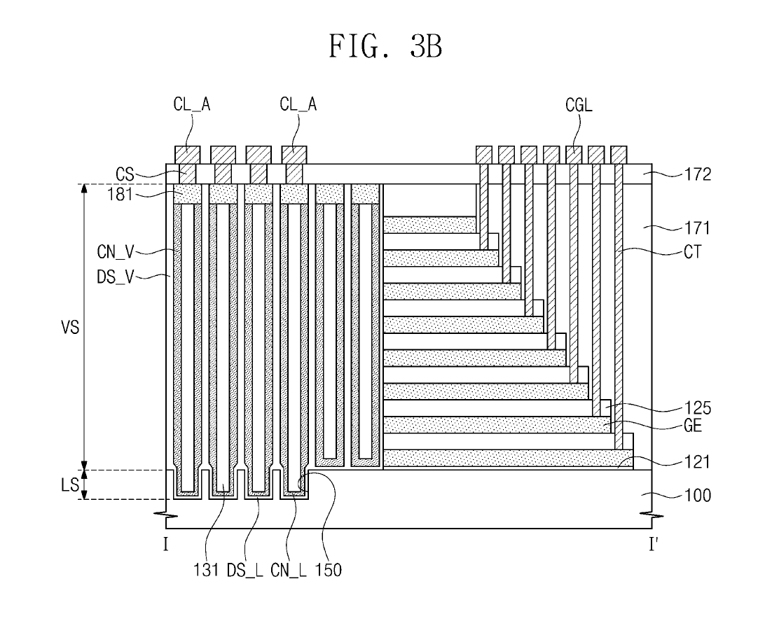

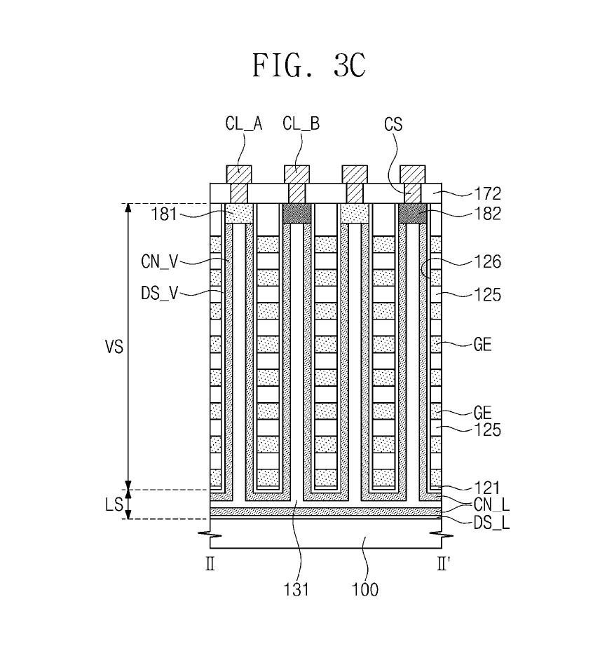

FIG. 3A depicts a plan view of a semiconductor device according to exemplary embodiments of the present inventive concept. FIG. 3B depicts a cross-sectional view taken along line I-I′ in FIG. 3A. FIG. 3C depicts a cross-sectional view taken along line II-II′ in FIG. 3A.

Referring to FIGS. 3A to 3C, an electrode structure may be provided that includes gate electrodes GE that are sequentially stacked on a semiconductor layer, such as, but not limited to, a substrate 100. The substrate 100 may be a semiconductor substrate having a first conductivity, for example, a p-type conductivity. The semiconductor substrate may be a single crystalline silicon layer, an SOI (silicon on insulator) substrate, a silicon layer formed on a silicon-germanium (SiGe) layer, a single crystalline silicon layer formed an insulation layer, or a polysilicon layer formed on an insulation layer.

The substrate 100 may include a cell array region CAR provided with memory cells, a contact region CTR for connecting the gate electrodes GE to interconnect lines, and a boundary region BR that is between the cell array region CAR and the contact region CTR. Each of the gate electrodes GE may extend in a first direction D1 and be configured into a stepwise structure for connecting with the interconnect lines in the contact region CTR. That is, each of the gate electrodes GE may have a length in the first direction D1 that is less than a length of an immediately underlying gate electrode GE, Thus, each gate electrode GE may expose pad portions PD that are connected to contacts, as described below. The pads PD may be covered with a first interlayer dielectric layer 171. In one embodiment, the first interlayer dielectric layer 171 may include a silicon oxide layer.

A buffer dielectric layer 121 may be provided between the substrate 100 and the gate structure. In one embodiment, the buffer dielectric layer 121 may be a silicon oxide layer. Insulation patterns 125 may be provided between the vertically stacked gate electrodes GE. The insulation patterns 125 may include a silicon oxide layer or a silicon oxynitride layer. The respective insulation patterns 125 may have the same thickness, but the present inventive concept is not limited thereto. For example, an uppermost insulation pattern 125 may have a thickness that is greater than the respective thicknesses of the insulation pattern 125 underlying the uppermost insulation pattern 125. In one embodiment, the buffer dielectric layer 121 may be thinner than the insulation patterns 125. The gate electrodes GE may include doped silicon, metal (e.g., tungsten), metal nitride, metal silicide, or a combination thereof. Although the figures depict eight vertically stacked gate electrodes GE, the number of the stacked gate electrodes GE may be greater or less than that depicted in the figures.

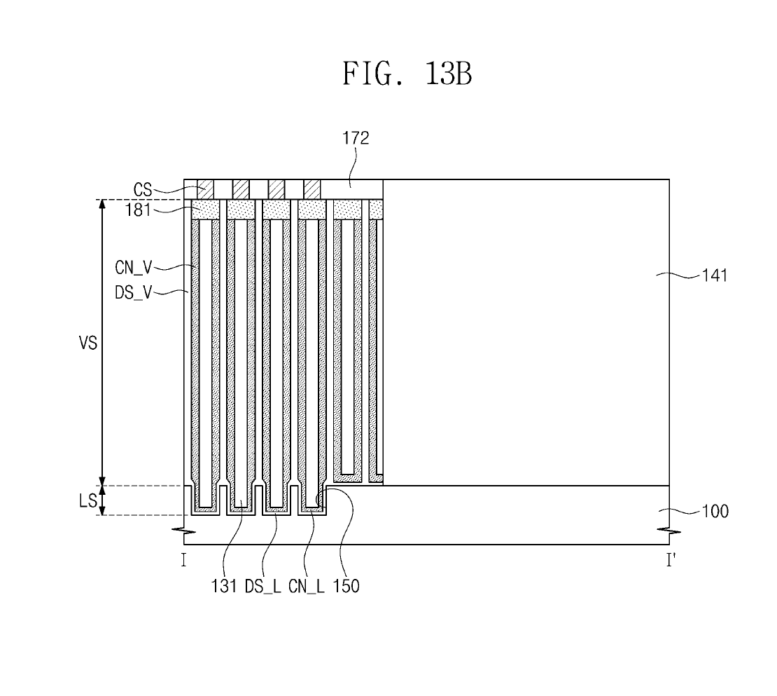

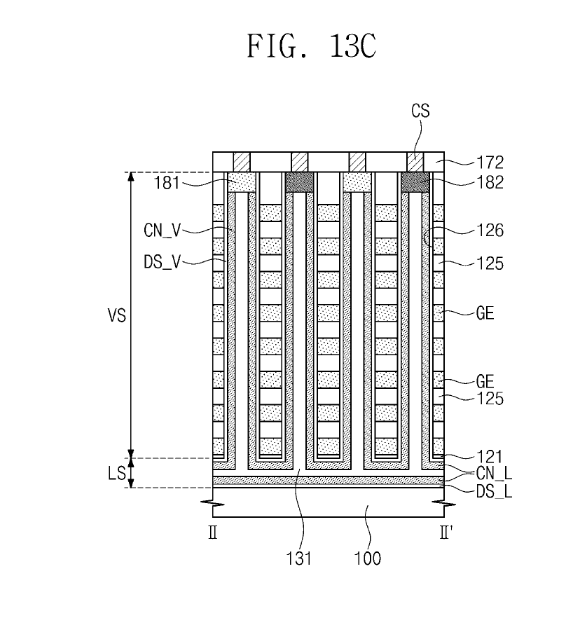

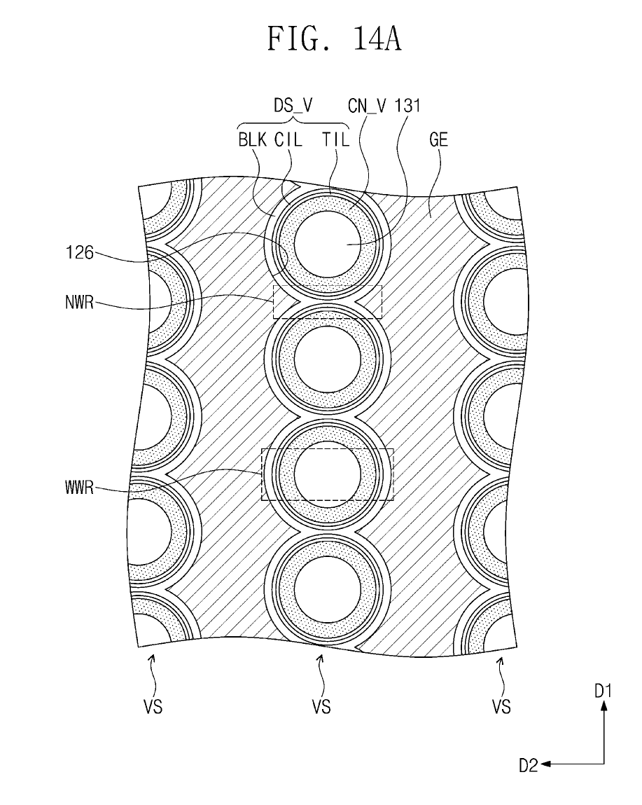

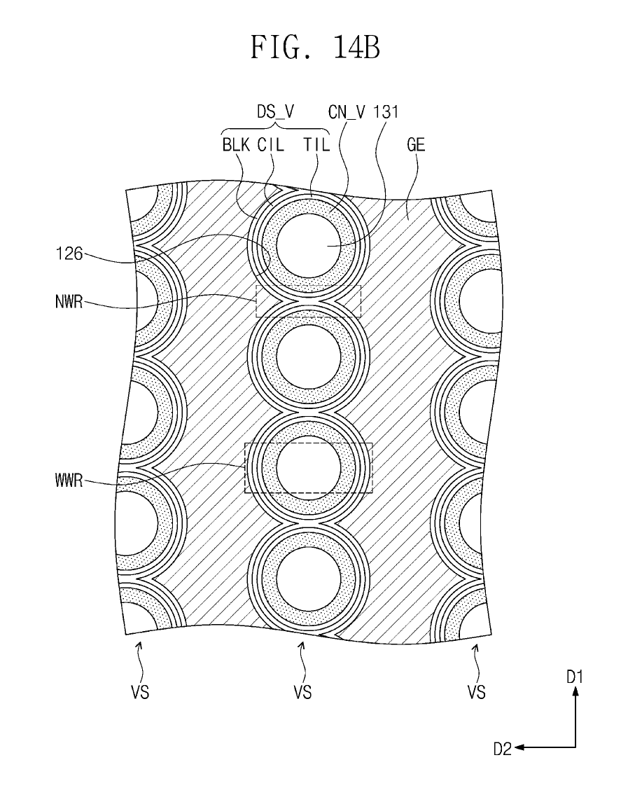

Vertical structures VS may be provided that separate the gate electrodes GE from each other in a second direction D2 that crosses the first direction D1. For example, the second direction D2 may be perpendicular or substantially perpendicular to the first direction D1. In other words, the gate electrodes GE that are disposed at the same level from a top surface of the substrate 100 may be separated from each other in the second direction D2 by the vertical structures VS that extend in the first direction D1. The vertical structures VS may be provided in openings 126 that extend in the first direction D1. Each of the openings 126 may have a shape that includes wide sections WWR and narrow sections NWR (see FIGS. 14A and 14B) that are disposed alternately and repeatedly in both of the second direction D2, and the first direction D1. For example, as viewed in a plan view, each of the openings 126 may have a circular or substantially circular shape that is arranged along the first direction D1 that partially overlaps an adjacent opening 126.

Each of the vertical structures VS may include vertical channel patterns CN_V that extend vertically and penetrate the gate electrodes GE. The vertical channel patterns CN_V may be regions where transistor channels are formed. The vertical channel patterns CN_V may include silicon, germanium, or silicon-germanium. In one embodiment, the vertical channel patterns CN_V may be, for example, polycrystalline (e.g., polysilicon). The vertical channel patterns CN_V may have the first conductivity type, i.e., a p-type conductive semiconductor pattern, but the vertical channel patterns CN_V are not limited to the first conductivity type. Alternatively, the vertical channel patterns CN_V may have an intrinsic state. The vertical channel patterns CN_V of adjacent vertical structures VS may be offset from each other in the first direction D1 so that they do not overlap. As a result, the vertical channel patterns CN_V may form columns that align in a third direction D3 in which the third direction D3 forms acute angles with both the first direction D1 and the second direction D2 when viewed in a plan view.

A vertical data storage layer DS_V may be provided between the vertical channel patterns CN_V and the gate electrodes GE. The vertical channel patterns CN_V of a vertical structure VS may be separated from each other in the first direction D1. That is, the vertical data storage layer DS_V may extend between and electrically separate the vertical channel patterns CN_V that are adjacent to each other in the first direction D1. A data storage layer that includes the vertical data storage layer DS_V will be discussed in further detail with reference to FIGS. 14A and 14B.

The vertical structures VS may each include filling insulation layers 131 that are each surrounded by a vertical channel pattern CN_V. In one embodiment, the filling insulation layers 131 may include a silicon oxide layer or a silicon oxynitride layer. Alternatively, the filling insulation layers 131 may be omitted.

The vertical structures VS may extend in the first direction D1 from the cell array region CAR into the boundary region BR. The boundary region BR may be a region where ends of the vertical structures VS are disposed. Separation insulation patterns 141 may be provided to overlap the ends of the vertical structures VS and extend from the boundary region BR into the contact region CTR. The insulation patterns 141 horizontally separate the gate electrodes GE. Each of the separation insulation patterns 141 may be provided in a separation trench 140. As viewed in a plan view, the separation trench 140 may overlap ends of each of the vertical structures VS and extend in the first direction D1 toward the contact region CTR. The vertical structures VS and the separation insulation patterns 141 may physically and electrically separate the gate electrodes GE that are adjacent to each other in the second direction D2. In other words, the gate electrodes GE may be horizontally spaced apart from each other across one vertical structure VS and a corresponding separation insulation pattern 141 that extends from the vertical structure VS, and thus different voltages may be applied to the gate electrodes GE, as described in an operation below. The separation insulation patterns 141 may include silicon oxide, silicon nitride, silicon oxynitride or a combination thereof. Although the separation insulation patterns 141 are depicted as having a width in the second direction D2 that is less than a width of the vertical structures VS in the second direction D2, in an alternative embodiment, the separation insulation patterns 141 may have a width that is greater than the width of the vertical structures VS in the second direction D2.

Horizontal structures LS may be provided between the vertical structures VS and the substrate 100. The horizontal structures LS may be provided embedded in an upper portion of the substrate 100 or, alternatively, may be provided in a layer (e.g., a polycrystalline silicon layer) formed on the substrate 100. For example, the horizontal structures LS may be provided in interconnect trenches 150 formed on an upper portion of the substrate 100. Each of the horizontal structures LS may extend in the third direction D3 that crosses both of the first and second directions D1 and D2. The horizontal structures LS may include horizontal channel patterns CN_L and horizontal data storage layers DS_L.

Each of the horizontal structures LS may be connected to lower portions of the vertical structures VS that the horizontal structure LS crosses. The horizontal channel pattern CN_L of each respective horizontal structure LS may be commonly connected to the vertical channel patterns CN_V that are arranged along the third direction D3 that the horizontal structure LS crosses in which the third direction D3 forms acute angles with both the first direction D1 and the second direction D2 when viewed in a plan view. Similarly, the horizontal data storage layer DS_L of each respective horizontal structure LS may be commonly connected to the vertical data storage layers DS_L that are arranged along the third direction D3 that the horizontal structure LS crosses. The horizontal channel patterns CN_L and the horizontal data storage layers DS_L extend along a corresponding interconnect trench 150. The horizontal channel patterns CN_L may be separated from the substrate 100 by the horizontal data storage layers DS_L being interposed between the horizontal channel layers CN_L and the substrate 100. Each of the filling insulation layers 131 may be connected from inner sidewalls of the vertical channel patterns CN_V to an inner sidewall of the horizontal channel pattern CN_L.

The horizontal structures LS may be provided in the cell array region CAR, but not in the boundary region BR and the contact region CTR. A boundary between the cell array region CAR and the boundary region BR may be defined as a virtual line that runs along the ends of the horizontal structures LS. The vertical channel patterns CN_V in the boundary region BR may not be connected to the horizontal channel patterns CN_L. Namely, the vertical channel patterns CN_V in the boundary region BR may be dummy cells that do not form memory cells.

First pads 181 and second pads 182 may be provided on the vertical channel patterns CN_V distal from the substrate 100. The first and second pads 181 and 182 may be spaced apart from each other on each of the vertical channel patterns CN_V. Although the first and second pads 181 and 182 are depicted as being provided on the uppermost insulation pattern 125 and in which the vertical data storage layers DS_V are depicted as interposed between the uppermost insulation pattern and the first and second pads 181 and 182, the first and second pads 181 and 182 may alternatively be provided in another insulation layer or in contact with the uppermost insulation pattern. The first and second pads 181 and 182 may be, for example, doped semiconductor patterns.

The first pads 181 may have a different conductivity from the conductivity of the second pads 182. For example, the first pads 181 may be p-type conductivity semiconductor patterns and the second pad 182 may be n-type conductivity semiconductor patterns. The same type pads may be provided on the vertical channel patterns CN_V in one vertical structure VS. For example, the first pads 181 may be provided on the vertical channel patterns CN_V of even-numbered vertical structures VS, and the second pads 182 may be provided on the vertical channel patterns CN_V of odd-numbered vertical structures VS. The first pad 181 and the second pad 182 may be alternately and repeatedly disposed on the vertical channel patterns CN_V connected to a horizontal structure LS.

Cell studs CS may be provided on the first and second pads 181 and 182. The cell studs CS may be provided on the first and second pads 181 and 182 that are in the cell array region CAR, but not on the first and second pads 181 and 182 that are in the boundary region BR. Alternatively, the vertical channel patterns CN_V in the boundary region BR may have no first and second pads 181 and 182, or may have no first and second pads 181 and 182 and no cell studs CS.

Conductive lines CL_A and CL_B may be provided that extend in the second direction D2 and may connect the cell studs CS that are aligned in the second direction D2 to each other. For clarity of the drawings, FIG. 3A shows that the conductive lines CL_A and CL_B are provided only on some of the cell studs CS, in which first conductive lines CL_A and second conductive lines CL_B may be repeatedly and alternately arranged in the first direction D1. The cell studs CS may be provided in a second interlayer dielectric layer 172, which may be on the first interlayer dielectric layer 171. The first conductive lines CL_A may be connected to the vertical channel patterns CN_V of the even-numbered vertical structures VS. Similarly, the second conductive lines CL_B may be connected to the vertical channel patterns CN_V of the odd-numbered vertical structures VS. In other words, the first conductive lines CL_A may be connected to the first pads 181 through corresponding cell studs CS, and the second conductive lines CL_B may be connected to the second pads 182 through corresponding cell studs CS.

The contact region CTR may be provided with contacts CT connected to the gate electrodes GE. The pad portions PD of the gate electrodes GE may be respectively connected to the contacts CT that penetrates the first interlayer dielectric layer 171 and the second interlayer dielectric layer 172. As viewed in a plan view, the contacts CT may be arranged in a zigzag fashion along the second direction D2. That is, contacts CT that are aligned with each other in the second direction D2 may offset from other contacts that are aligned with each other in the second direction D2. Interconnect lines CGL may be disposed on the contacts CT. FIG. 3A shows that the interconnect lines CGL are disposed only on a few of the contacts CT for clarity of FIG. 3A. Each of the conductive lines CL_A and CL_B, the interconnect lines CGL, the cell studs CS, and the contacts CT may include a metal, a conductive metal nitride, or a doped semiconductor material.

FIGS. 14A and 14B depict plan views for explaining vertical data storage layers DS_V according to exemplary embodiments of the present inventive concept. The vertical data storage layers DS_V may include a blocking insulation layer BLK, a charge storage layer CIL, and a tunnel insulation layer TIL that are sequentially formed on a sidewall of each of the openings 126. The horizontal data storage layers DS_L may have substantially the same structure as the vertical data storage layers DS_V, although not shown in the figures. As discussed above, each of the openings 126 may have a shape that has wide sections WWR and narrow sections NWR that are alternately and repeatedly arranged in the second direction D2 so that the blocking insulation layer BLK and/or the charge storage layer CIL may be connected to each other in the narrow sections NWR. For example, as shown in FIGS. 14A, the blocking insulation layers BLK on opposing sidewalls of each of the openings 126 may be connected to each other in the narrow width regions NWR. As a result, the charge storage layer CIL, the tunnel insulation layer TIL, the vertical channel pattern CN_V, and the filling insulation layer 131 provided in each of the openings 126 may be formed to be separated from the charge storage layer CIL, the tunnel insulation layer TIL, the vertical channel pattern CN_V, and the filling insulation layer 131 of the neighboring openings 126 that are arranged in the first direction D1.

Alternatively, as shown in FIG. 14B, the charge storage layers CIL, as well as the blocking insulation layer BLK, on the opposing sidewalls of each of the openings 126 may also be connected to each other in the narrow width regions NWR. As a result, the tunnel insulation layer TIL, the vertical channel pattern CN_V, and the filling insulation layer 131 provided in each of the openings 126 may be formed to be separated from the tunnel insulation layer TIL, the vertical channel pattern CN_V, and the filling insulation layer 131 of the neighboring openings 126 that are arranged in the first direction D1.

The blocking insulation layer BLK may be a multiple layer structure that is formed by a plurality of thin layers. For example, the blocking layer BLK may include a hafnium oxide layer, an aluminum oxide layer, and/or a silicon oxide layer, in which the stacking order of the plurality of thin layers may be varied. The charge storage layer CIL may be an insulation layer that includes a charge trap layer or conductive nanoparticles. The charge trap layer may include, for example, a silicon nitride layer. The tunnel insulation layer TIL may include a silicon oxide layer. The tunnel insulation layer TIL may further include a high-k dielectric layer (e.g., a hafnium oxide layer or an aluminum oxide layer). In some embodiments, the vertical data storage layers DS_V may include variable resistance patterns. The variable resistance patterns may include a material having a variable resistance property.

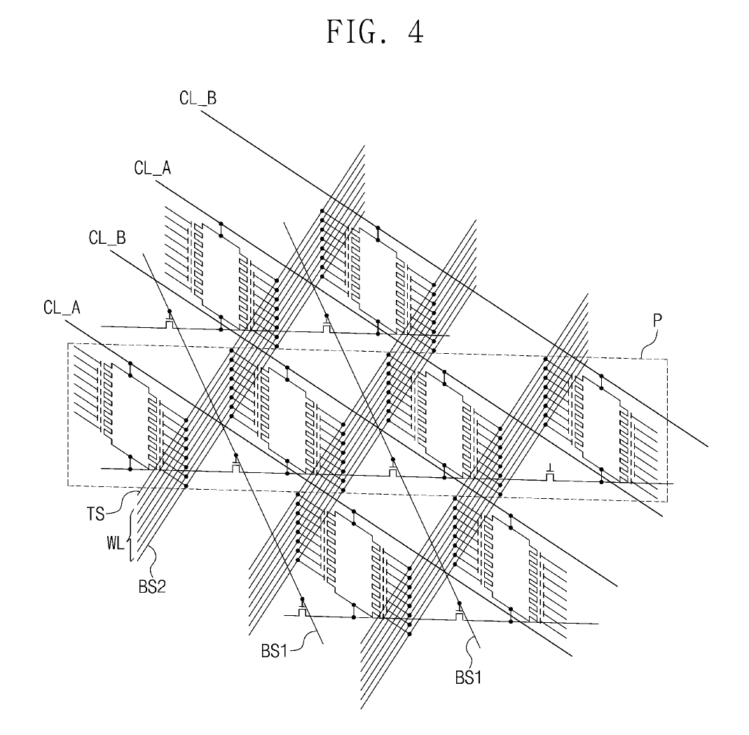

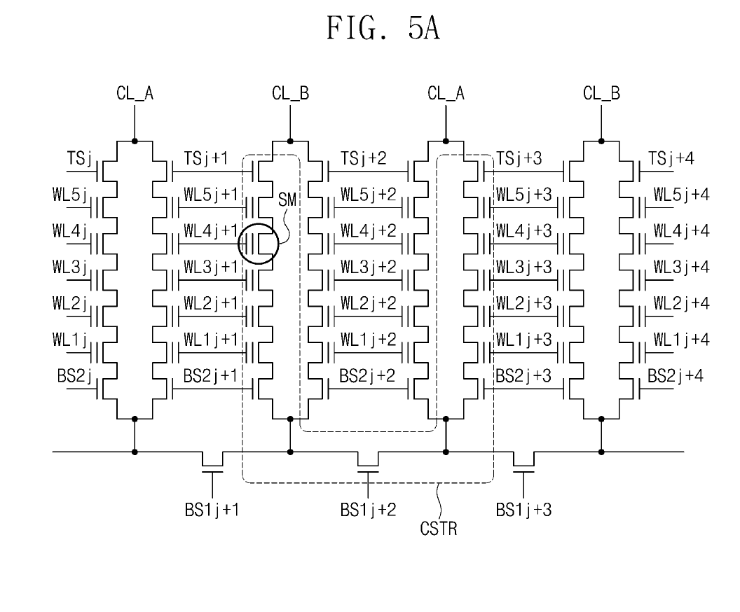

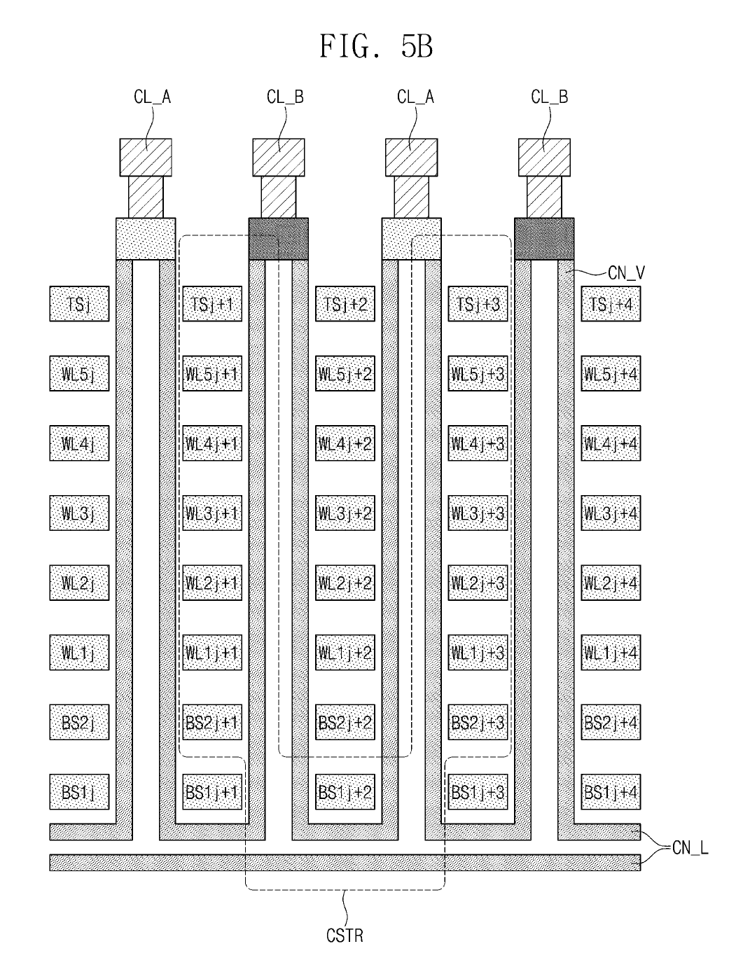

FIG. 4 depicts a circuit diagram of a cell array of a semiconductor device according to exemplary embodiments of the present inventive concept. FIG. 5A depicts a circuit diagram of one memory block corresponding to section P in FIG. 4. FIG. 5B depicts a diagram showing components of FIG. 5A that are connected to each gate electrode that differentiate the gate electrodes from each other.

Referring to FIGS. 4, 5A and 5B, the semiconductor device according to exemplary embodiments of the present inventive concept may include a plurality of cell strings CSTR that are disposed between the first conductive lines CL_A and the second conductive lines CL_B. The gate electrodes GE, discussed with reference to FIGS. 3A to 3C, may include uppermost or top select lines TS, lowermost or first bottom select lines BS1, word lines WL between the top select lines TS and the first bottom select lines BS1, and second bottom select lines BS2 between the first bottom select lines BS1 and lowermost word lines WL. Some of the top select lines TS, the first bottom select lines BS1, and the second bottom select lines BS2 are depicted as patterns at the same level that are separated from other top select lines TS, the first bottom select lines BS1, and the second bottom select lines BS2, but the present inventive concept is not limited thereto.

The first conductive lines CL_A may be common source lines, and the second conductive lines CL_B may be bit lines. Some of the top select lines TS may be gate electrodes of string select transistors, and the remaining top select lines TS may be gate electrodes of ground select transistors. For example, in the case of the cell strings CSTR depicted in FIGS. 5A and 5B, TSj+3 may be a gate electrode of a ground select transistor and TSj+1 may be a gate electrode of a string select transistor. The first bottom select lines BS1 may be switching gates for connecting or separating inversion layers formed in the vertical channel patterns CN_V in the vertical channel patterns CN_V that are adjacent to each other. The word lines WL may be gate electrodes of memory cell transistors. The second bottom select lines BS2 may be gates for connecting the memory cell transistors to the switching gates. Alternatively, the second bottom select lines BS2 may be omitted.

An operation of a semiconductor device according to exemplary embodiments of the present inventive concept will be described with reference back to FIGS. 5A and 5B. Table 1 below sets form the erase voltage conditions of the gate electrodes and the conductive lines. Under the conditions of Table 1, it may be possible to erase all of the memory cells in one memory block. Hereinafter, “On” denotes that a transistor is turned on and “OFF” means that a transistor is turned off.

TABLE 1
Erase Voltage Conditions of Gate Electrodes and Conductive Lines

| Component | Condition |
|---|---|
| CL_A | Verase |
| CL_B | Floating |
| WL | 0 V |
| TSj~TSj + 4 | Floating |
| BS2j~BS2j + 4 | On |
| BS1j + 1~BS1j + 3 | On |
| Substrate (or corresponding structure) | Floating |

Table 2 below sets forth the write voltage conditions of the gate electrodes and the conductive lines. Under the conditions of Table 2, a cell string CSTR of FIG. 5A may be selected and a write operation may be performed on a selected memory cell SM of a selected cell string CSTR. An inhibiting voltage VIN may be a voltage for preventing the selected cell string CSTR from being written. A program voltage Vpgm may be a sufficiently high voltage to cause a Fowler-Nordheim (FN) tunneling from the channel, and a pass voltage Vpass may be selected from a voltage range from greater than a threshold voltage Vth of a memory cell transistor to less than the program voltage Vpgm of the memory cell. A write operation according to an exemplary embodiment may include a selective programming step that prevents programming of memory cells that are included in inhibited strings and unselected strings, and programs memory cells that are included in selected strings using a self-boosting technique.

TABLE 2
Write Voltage Conditions of Gate Electrodes and Conductive Lines

| Component | | | Condition |
|---|---|---|---|
| CL_A of selected string | | | GND |
| CL_B of selected string | | | 0 V |
| CL_A, CL_B of unselected string | | | VIN |
| | WL | WLxJ + 1, WLxJ + 3 | Vₚₐₛₛ |
| | | WLxJ + 2 | Vᵣₑᵥₑᵣₛₑ |
| | | WL4j + 1(selected) | V_{pgm} |
| | TS | TSj + 1, TSj + 3 | Vₚₐₛₛ |
| | | TSj + 2 | Vᵣₑᵥₑᵣₛₑ |
| | BS2 | BS2j + 1, BS2j + 3 | Vₚₐₛₛ |
| | | BS2j + 2 | Vᵣₑᵥₑᵣₛₑ |
| | BS1j | BS1j + 2 | ON |
| | | BS1j + 1, BS1j + 3 | OFF |

| | |
|---|---|
| Substrate (or corresponding structure) | Vᵣₑᵥₑᵣₛₑ |

Table 3 below sets forth the read voltage conditions of the gate electrodes and the conductive lines. Under the conditions of Table 3, the cell string CSTR of FIG. 5A may be selected and a read operation may be performed on a selected memory cell SM of a selected cell string CSTR. A bit line voltage VBL may be a predetermined voltage (e.g., a voltage supplied from an external source) that is greater than a threshold voltage Vth.

TABLE 3
Read Voltage Conditions of Gate Electrodes and Conductive Lines

| Component | | | Condition |
|---|---|---|---|
| CL_A of selected string | | | GND |
| CL_B of selected string | | | VBL |
| CL_A, CL_B of unselected string | | | GND |
| | WL | WLxJ + 1, WLxJ + 3 | Vₚₐₛₛ |
| | | WLxJ + 2 | Vᵣₑᵥₑᵣₛₑ |
| | | WL4j + 1(selected) | V_{read} |
| | TS | TSj + 1, TSj + 3 | Vₚₐₛₛ |
| | | TSj + 2 | Vᵣₑᵥₑᵣₛₑ |
| | BS2 | BS2j + 1, BS2j + 3 | Vₚₐₛₛ |
| | | BS2j + 2 | Vᵣₑᵥₑᵣₛₑ |
| | BS1j | BS1j + 2 | ON |
| | | BS1j + 1, BS1j + 3 | OFF |

| | |
|---|---|
| Substrate (or corresponding structure) | Vᵣₑᵥₑᵣₛₑ |

A pair of adjacent vertical channel patterns CN_V connected to one horizontal channel pattern CN_L may behave as a channel region of the same cell string. As discussed above, gate electrodes that are spaced apart from each other across one vertical channel pattern CN_V may be electrically separated from each other and may be supplied with different voltages. Thus, one vertical channel pattern CN_V may be shared by two cell strings CSTR. Additionally, one vertical channel pattern CN_V and gate electrodes spaced apart from each other across the vertical channel pattern CN_V may behave as a pair of different cell strings CSTR. Accordingly, it may be possible to increase an integration of semiconductor device because a single vertical structure VS provides two different cell strings CSTR.

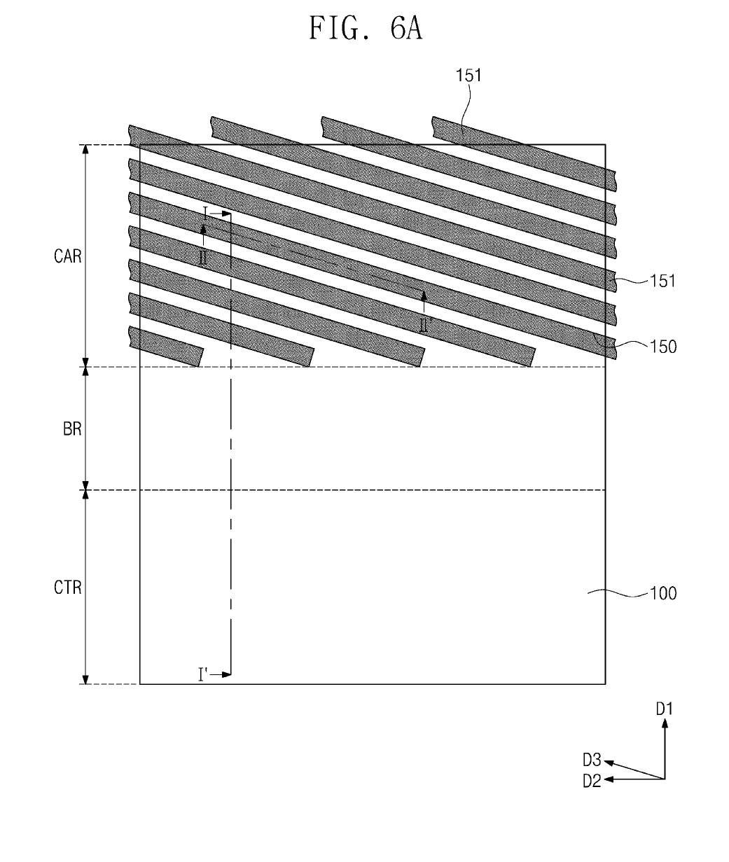

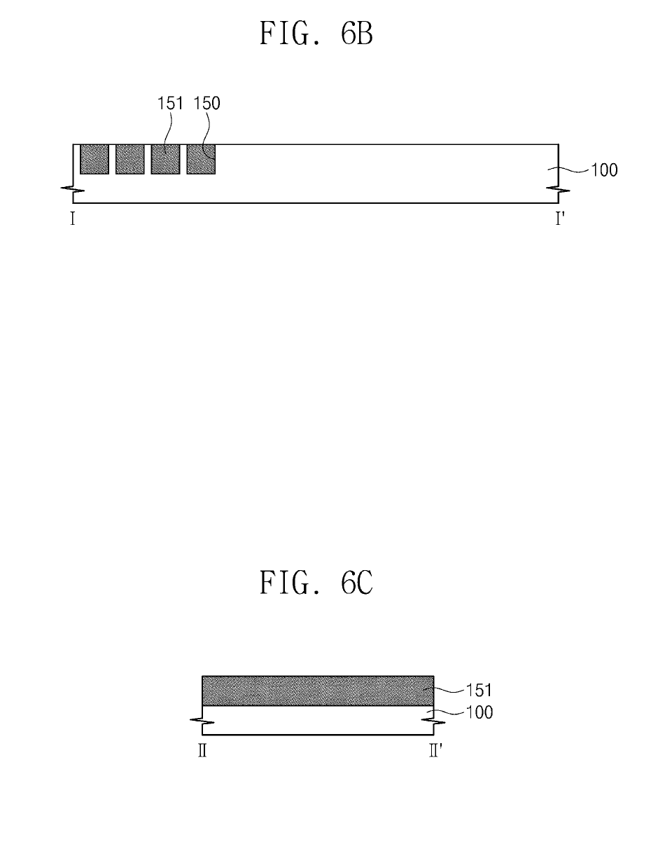

FIGS. 6A to 13A respectively depict plan views for explaining a method for fabricating a semiconductor device according to exemplary embodiments of the present inventive concept. FIGS. 6B to 13B respectively depict cross-sectional views taken along line I-I′ in FIGS. 6A to 13A. FIGS. 6C to 13C respectively depict cross-sectional views taken along line II-II′ in FIGS. 6A to 13A.

Referring to FIGS. 6A to 6C, a substrate 100 may be provided. The substrate 100 may have a first conductivity type, for example, a p-type conductivity. The substrate 100 may include a cell array region CAR having memory cells, a contact region CTR for connecting gate electrodes to interconnect lines, and a boundary region BR between the cell array region CAR and the contact region CTR.

Interconnect trenches 150 may be formed in an upper portion of the substrate 100. Each of the interconnect trenches 150 may extend in a third direction D3. The interconnect trenches 150 may be formed by a dry-etch process. The interconnect trenches 150 may be formed in the cell array region CAR, but not in the boundary region BR or the contact region CTR.

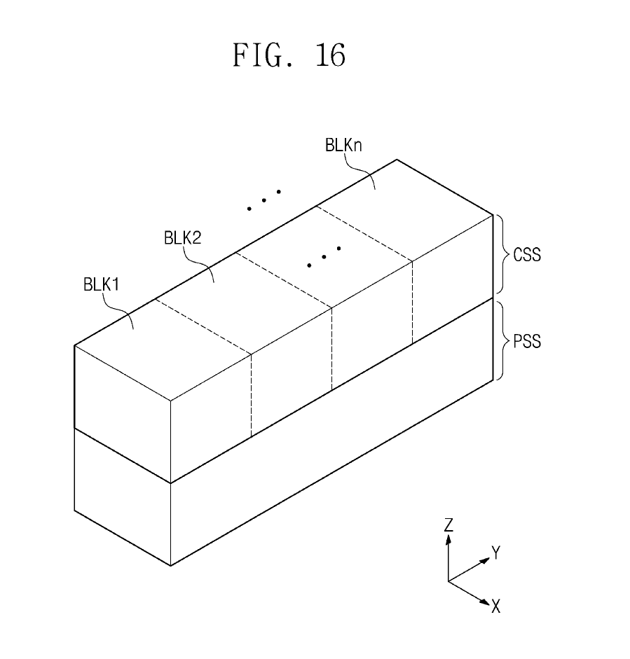

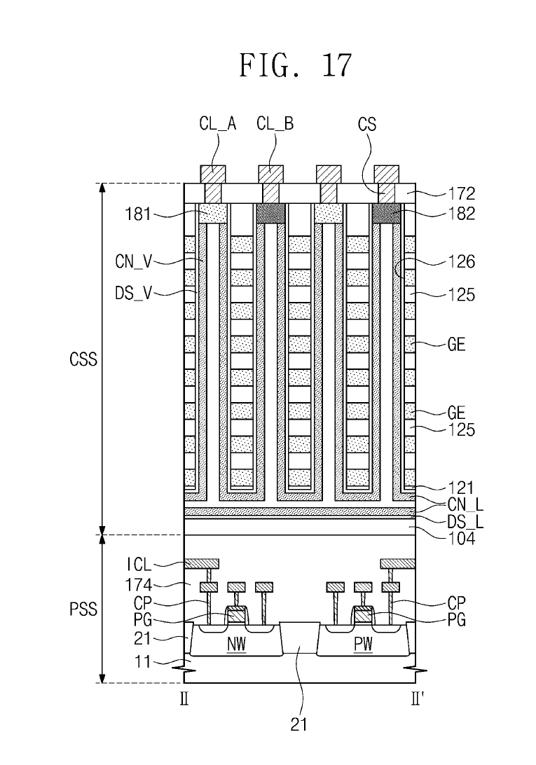

Sacrificial patterns 151 may be formed to fill the interconnect trenches 150. The sacrificial patterns 151 may include a material having an etch selectivity with respect to gate electrodes and insulation patterns, which will be described below. For example, the sacrificial patterns 151 may include silicon nitride or silicon oxynitride. The sacrificial patterns 151 may be formed by an insulation layer that fills the interconnect trenches 150, and then performing a planarization process until a top surface of the substrate 100 is exposed. For brevity of the description below, the following description sets forth that the sacrificial patterns 151 are formed in the upper portion of the substrate 100. In another embodiment, the sacrificial patterns 151 may alternatively be formed in another layer that is formed on the substrate 100. An embodiment having the sacrificial layers 151 formed in another layer that is formed on the substrate 100 will be discussed with reference to FIGS. 16 and 17.

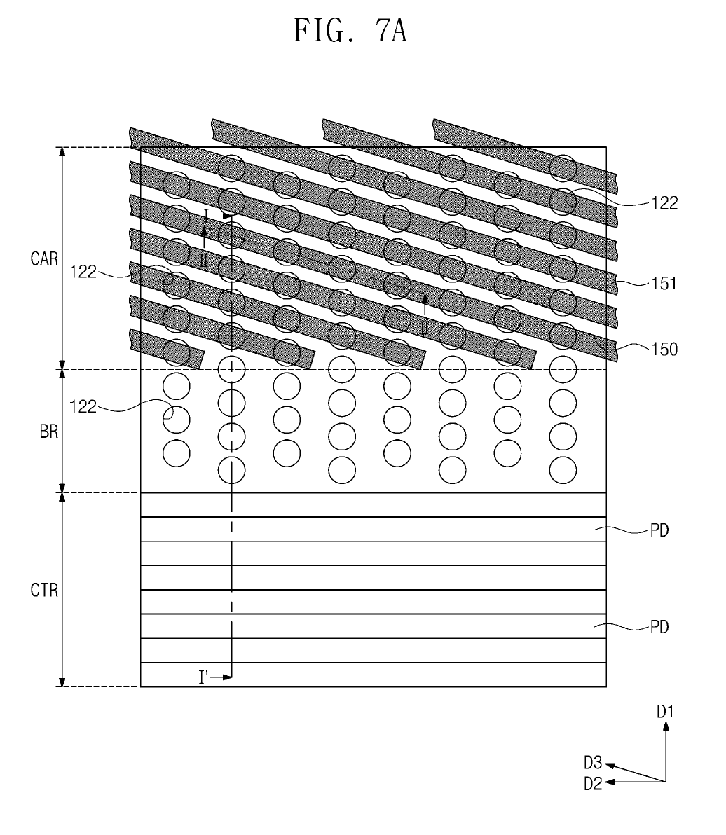

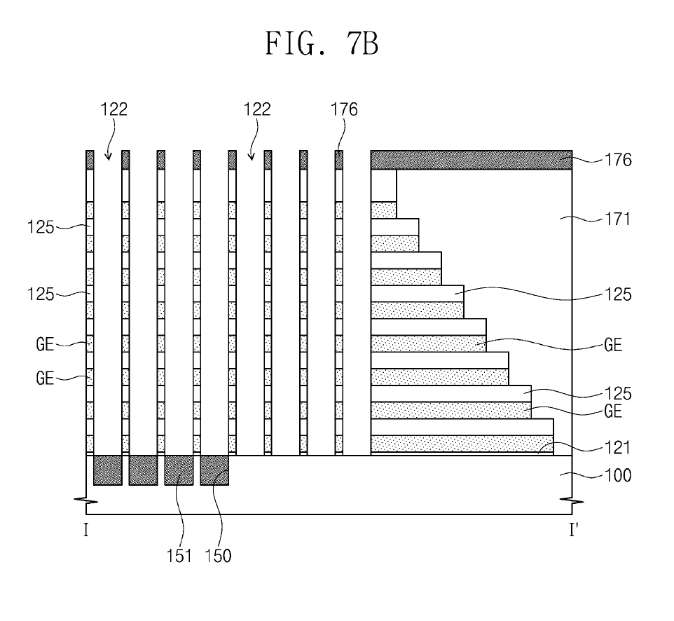

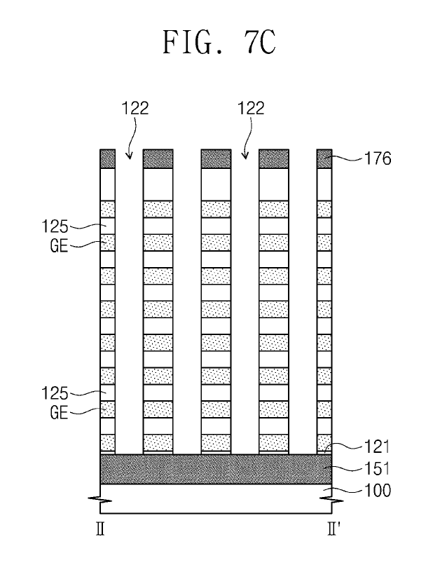

Referring to FIGS. 7A to 7C, a buffer dielectric layer 121 may be formed on the substrate 100. The buffer dielectric layer 121 may be formed from, for example, a silicon oxide layer. The buffer dielectric layer 121 may be formed by, for example, a thermal-oxidation process. Gate electrodes GE and insulation patterns 125 may be alternately and repeatedly formed on the buffer dielectric layer 121. The gate electrodes GE may include doped silicon, metal (e.g., tungsten), metal nitride, metal silicide, or any combination thereof. The insulation patterns 125 may include a silicon oxide layer or a silicon oxynitride layer. An uppermost insulation pattern 125 may have a thickness that is greater than the thicknesses of the insulation patterns 125 underlying the uppermost insulation pattern 125. The buffer dielectric layer 121, the gate electrodes GE, and the insulation patterns 125 may be formed by a chemical vapor deposition (CVD) or a physical vapor deposition (PVD).

Pad portions PD may be formed in the contact region CTR. The pad portions PD may be ends of the gate electrodes GE that have a stepwise structure. In other words, each of the gate electrodes GE may have a length in the first direction D1 less than a length of an immediately underlying gate electrode GE. The insulation patterns 125 in contact with top surfaces of corresponding gate electrodes GE may have the same length as the gate electrodes GE as measured in the first direction D1. The formation of the pad portions PD may include forming of a mask pattern and a plurality of trimming processes for reducing a width of the mask pattern. For example, the trimming processes may be performed using an isotropic dry-etch method or a wet-etch method. A first interlayer dielectric layer 171 may be formed to cover the pad portions PD. The first interlayer dielectric layer 171 may include a silicon oxide layer.

Vertical holes 122 may be formed to penetrate the gate electrodes GE, the insulation patterns 125, and the buffer dielectric layer 121. The vertical holes 122 may be formed in the cell array region CAR and the boundary region BR. The vertical holes 122 may be formed by an anisotropic-etch process. For example, mask patterns 176 may be formed on the uppermost insulation pattern 125 and then an anisotropic-etch process may be performed using the mask patterns 176 as an etch mask. The mask patterns 176 may include a material having an etch selectivity with respect to the insulation patterns 125. For example, in the case that the insulation patterns 125 are silicon oxide layers, the mask patterns 176 may be silicon nitride layers or silicon oxynitride layers.

A distance between the vertical holes 122 that are adjacent to each other in a second direction D2 may be greater than a distance between the vertical holes 122 that are adjacent to each other in the first direction D1. The vertical holes 122 may be aligned to form columns in the first direction D1 as viewed in a plan view. The position of the vertical holes 122 of adjacent columns may be offset in the first direction D1 so to be aligned with the sacrificial patterns 151. As a result, a plurality of the vertical holes 122 may be arranged on each of the sacrificial patterns 151. In the cell array region CAR, the vertical holes 122 may expose top surfaces of the sacrificial patterns 151 and, in the boundary region BR, expose the top surface of the substrate 100.

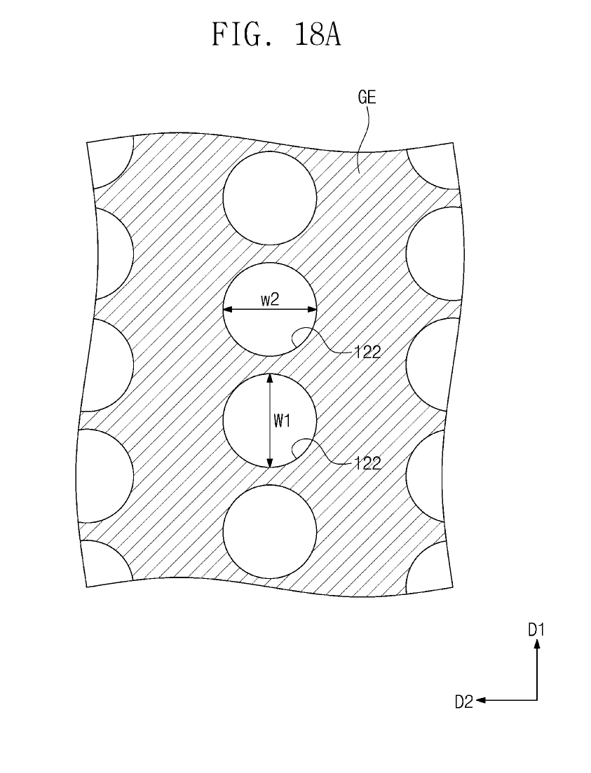

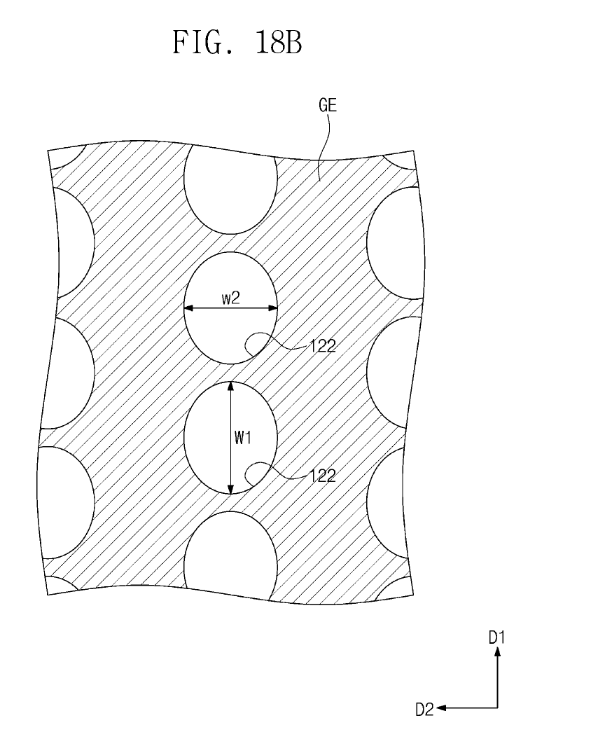

Shapes of the vertical holes 122 are described with reference to FIGS. 18A and 18B. As shown in FIG. 18A, each of the vertical holes 122 may have a width w1 in the first direction D1 that is substantially the same as a width w2 in the second direction D2. Alternatively, as shown in FIG. 18B, each of the vertical holes 122 may have a width w1 in the first direction D1 that is greater than a width w2 in the second direction D2.

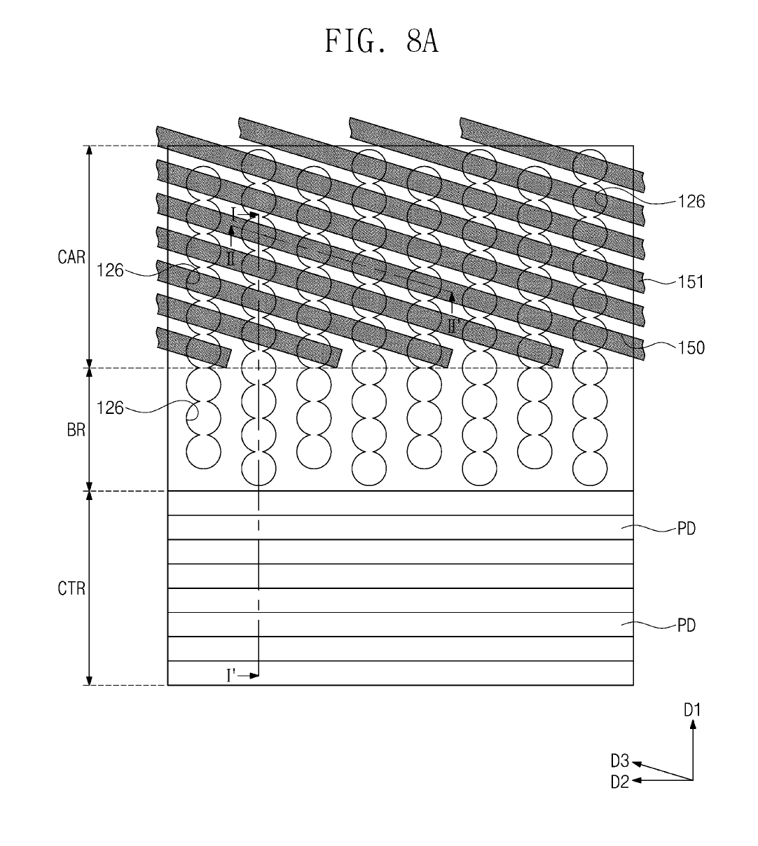

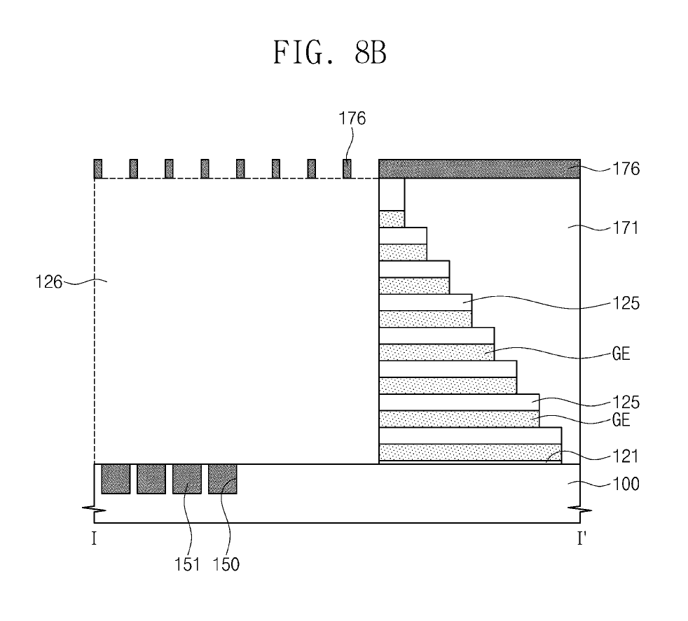

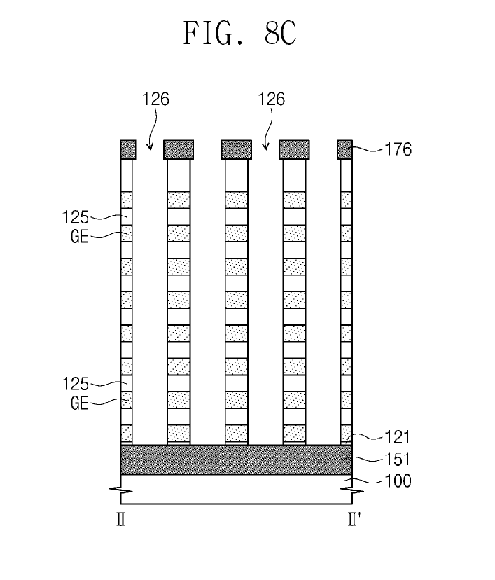

Referring to FIGS. 8A to 8C, the vertical holes 122 may be enlarged to form openings 126 that extend in the first direction D1. The enlargement of the vertical holes 122 may include a plurality of etch processes. For example, the enlargement of the vertical holes 122 may include an etch process on sidewalls of the gate electrodes GE and an etch process on sidewalls of the insulation patterns 125. The etching of the gate electrodes GE may be carried out using, for example, an SC1 solution, and the etching of the insulation patterns 125 may be carried out using, for example, HF. As the vertical holes 122 are enlarged, the vertical holes 122 may be connected to each other in the first direction D1 so that the openings 126 may be formed.

By the formation of the openings 126, the gate electrodes GE may be separated from each other in the second direction D2 across the openings 126. The insulation patterns 125 may also be separated from each other in the second direction D2 across the openings 126. The sacrificial patterns 151 may remain without being removed in the cell array region CAR. Alternatively from the exemplary embodiment shown in figures, an upper portion of the substrate 100 may also be etched on the boundary region BR where the sacrificial patterns 151 are not formed. The mask patterns 176 may have holes for forming the vertical holes 122, and the holes of the mask patterns 176 may not be enlarged together with the vertical holes 122 so that the mask patterns 176 may structurally support the gate electrodes GE and the insulation patterns 125 below the mask patterns 176.

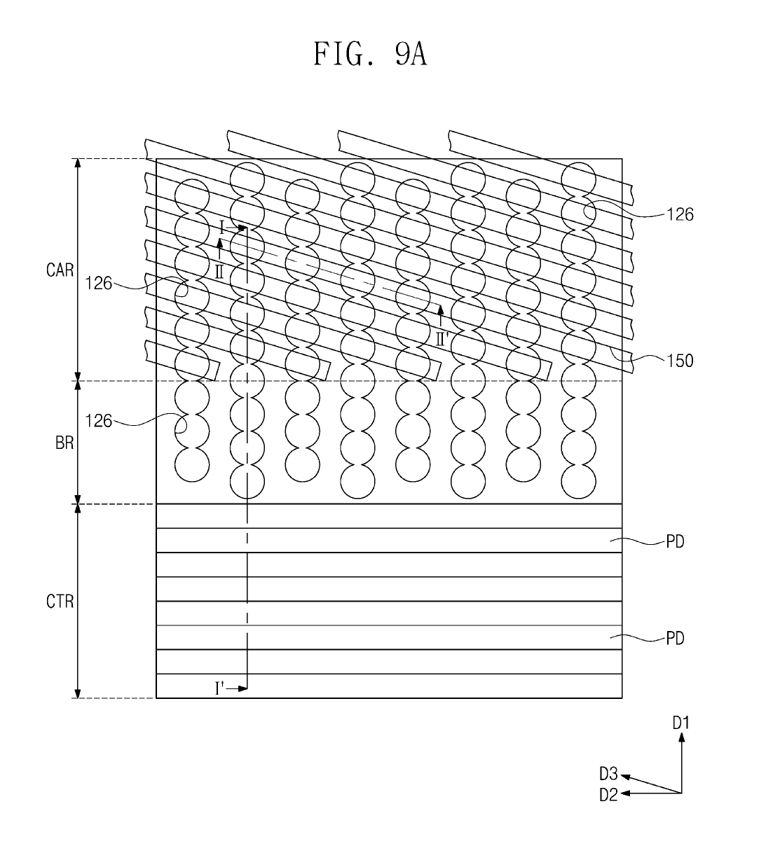

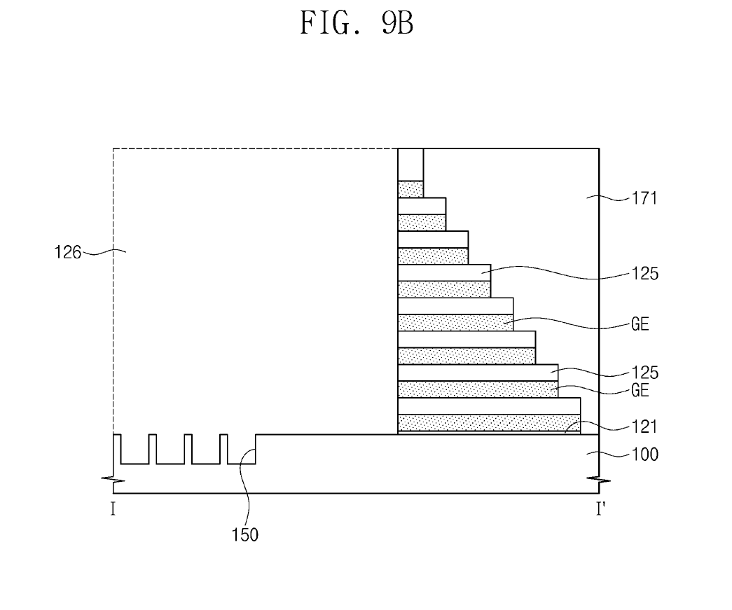

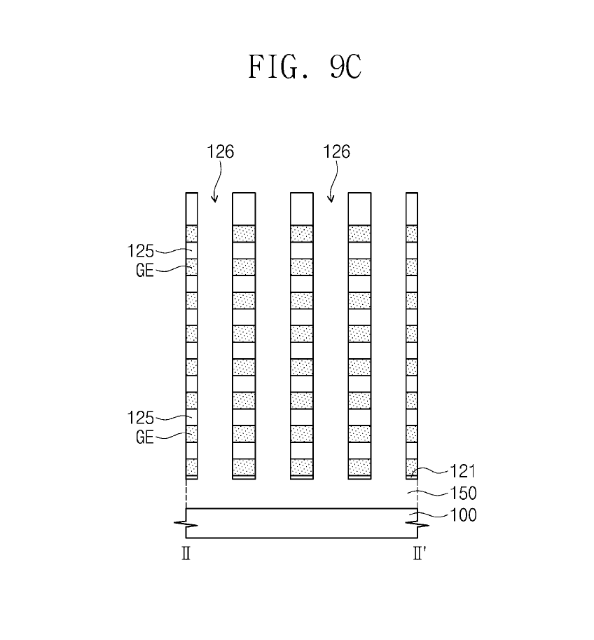

Referring to FIGS. 9A to 9C, the sacrificial patterns 151 may be selectively removed. The removal of the sacrificial patterns 151 may be performed while minimizing the etching of the gate electrodes GE and the insulation patterns 125. For example, a phosphoric acid may be used to selectively remove the sacrificial patterns 151. The removal of the sacrificial patterns 151 may expose the interconnect trenches 150. The openings 126 may thus be connected to the interconnect trenches 150. The mask patterns 176 may be removed together with the insulation patterns 151, or may be removed by an individual etch process.

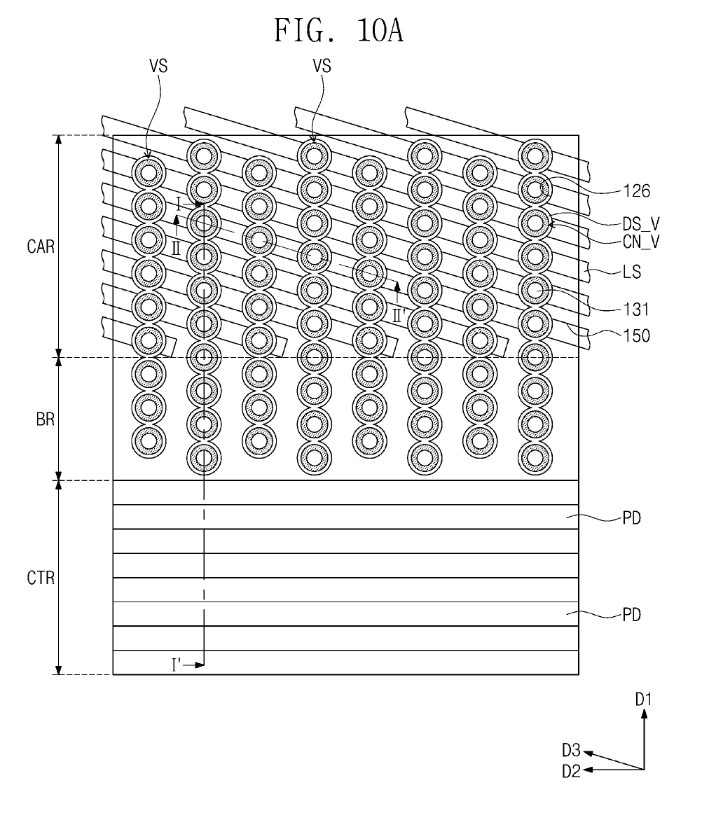

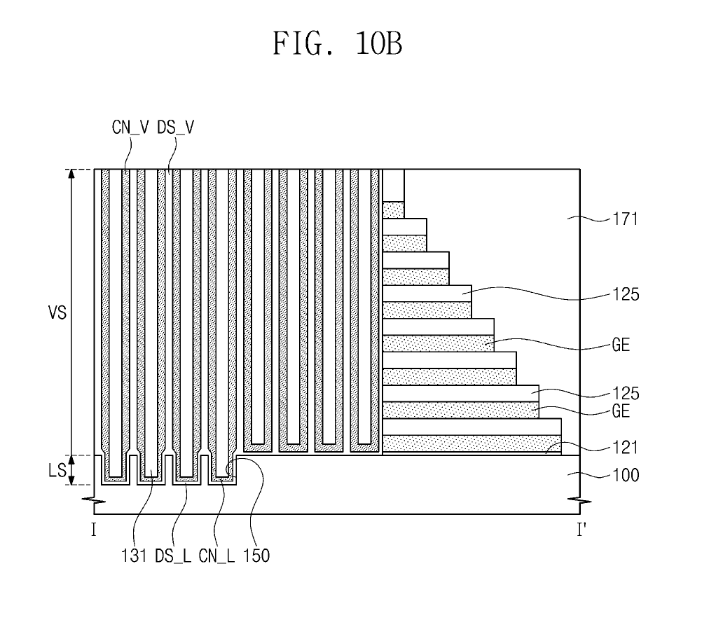

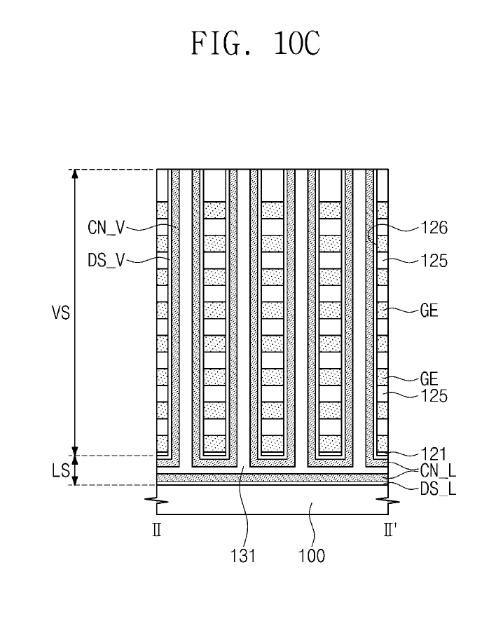

Referring to FIGS. 10A to 10C, data storage layers DS_V and DS_N, channel patterns CN_V and CN_L, and filling insulation layers 131 may be sequentially formed in the openings 126 and the interconnect trenches 150. Thus, vertical structures VS and horizontal structures LS may be formed. The vertical structures VS formed in the openings 126 may include vertical data storage layers DS_V and vertical channel patterns CN_V. The horizontal structures LS formed in the interconnect trenches 150 may include horizontal data storage layers DS_L and horizontal channel patterns CN_L.

The formations of the vertical structures VS and the horizontal structures LS may include an atomic layer deposition (ALD). The data storage layers DS_V and DS_N may have a structure as discussed with reference to FIGS. 14A and 14B. For example, the channel patterns CN_V and CN_L may be formed of a polysilicon layer, and the filling insulation layers 131 may be formed of a silicon oxide layer. Thereafter, a planarization process may be performed to expose a top surface of the uppermost insulation pattern 125.

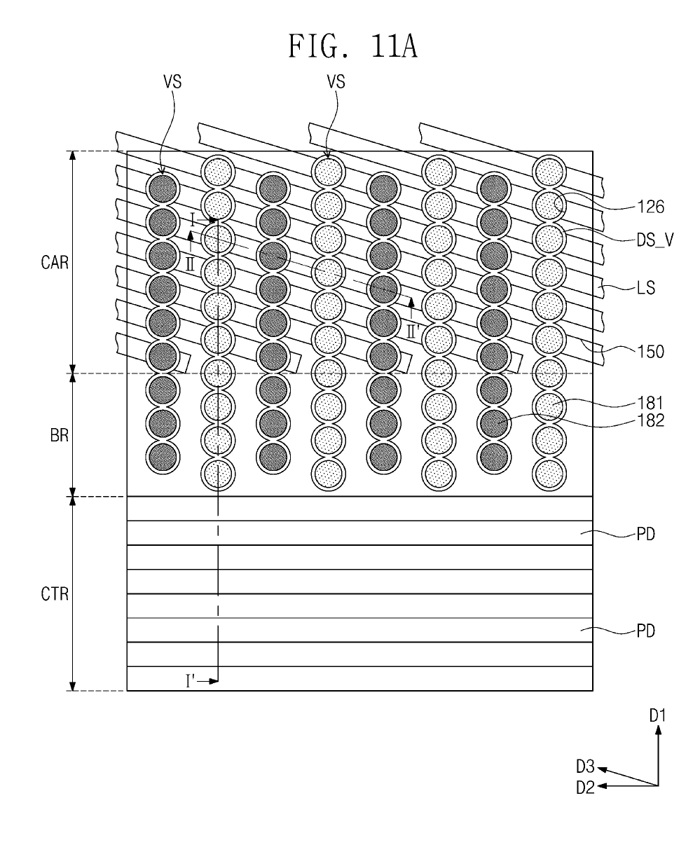

Referring to FIGS. 11A to 11C, first and second pads 181 and 182 may be formed on the vertical channel patterns CN_V. The first and second pads 181 and 182 may be spaced apart from each other on respective vertical channel patterns CN_V. For example, the first and second pads 181 and 182 may be formed by removing upper portions of the vertical channel patterns CN_V and upper portions of the filling insulation layers 131, and then filling the removed regions with a conductive material. For example, the first and second pads 181 and 182 may be formed of doped semiconductor patterns.

The first and second pads 181 and 182 may be formed by a plurality of ion-implantation processes. For example, the first pads 181 may a have different conductivity from the second pads 182. For example, the first pads 181 may be p-type conductivity semiconductor patterns, and the second pad 182 may be n-type conductivity semiconductor patterns. The same type pads may be provided on the vertical channel patterns CN_V in one vertical structure VS. For example, the first pads 181 may be provided on the vertical channel patterns CN_V of even-numbered vertical structures VS, and the second pads 182 may be provided on the vertical channel patterns CN_V of odd-numbered vertical structures VS.

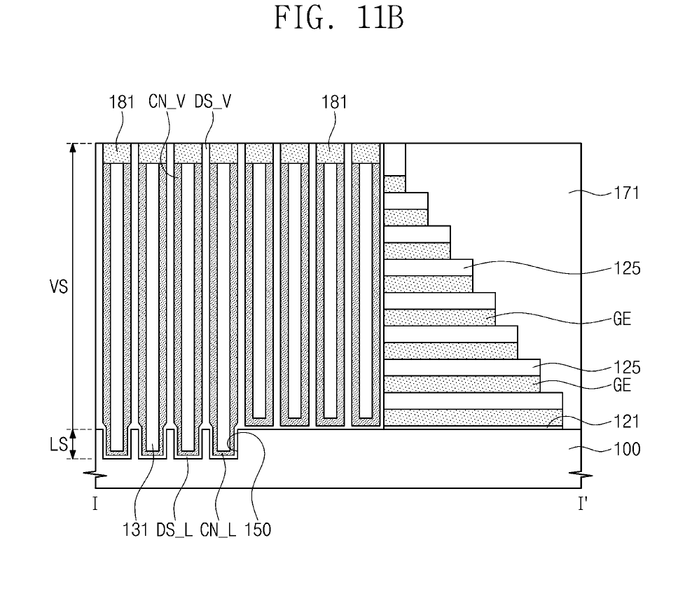

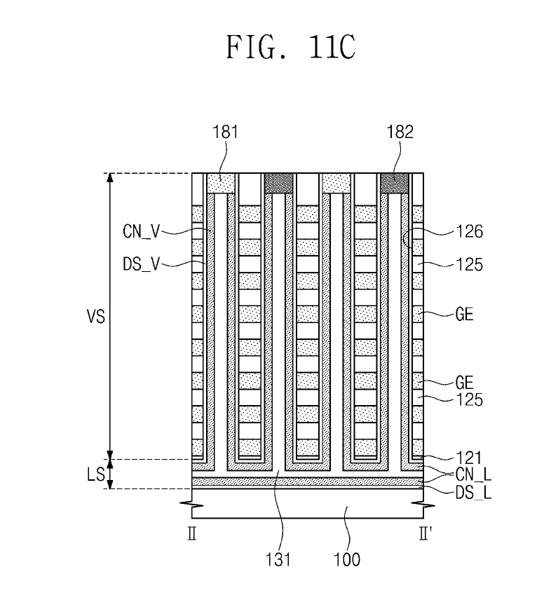

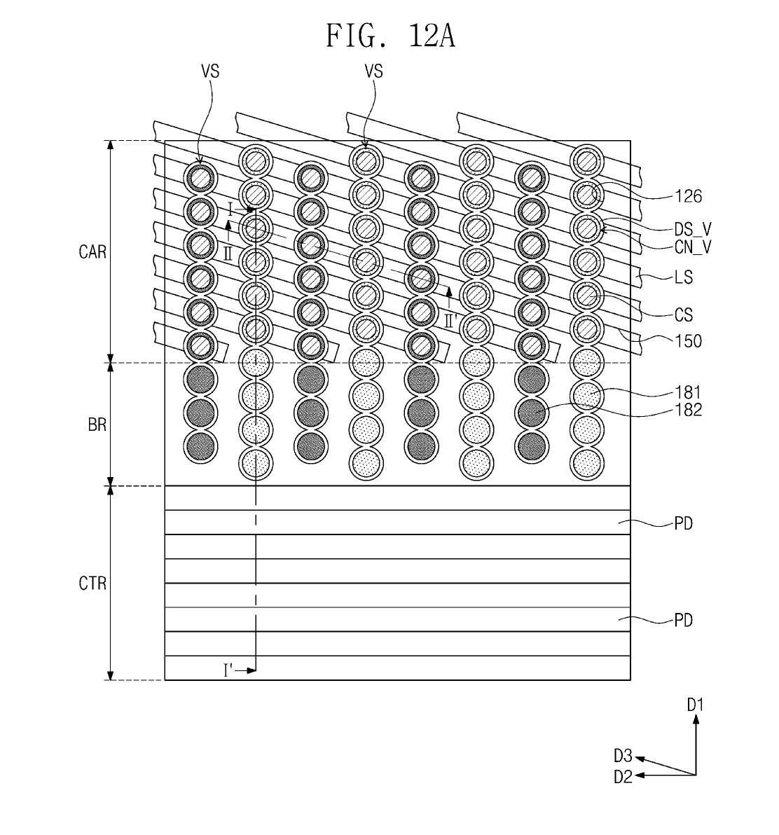

Referring to FIGS. 12A to 12C, a second interlayer dielectric layer 172 may be formed on the first and second pads 181 and 182, and then cell studs CS may be formed that are respectively connected to the first and second pads 181 and 182. The cell studs CS may be provided on the first and second pads 181 and 182 that are included in the cell array region CAR, but not on the first and second pads 181 and 182 that are included in the boundary region BR. The cell studs CS may include a metal, a conductive metal nitride, or a doped semiconductor material. The cell studs CS may be formed by, for example, a physical vapor deposition (PVD).

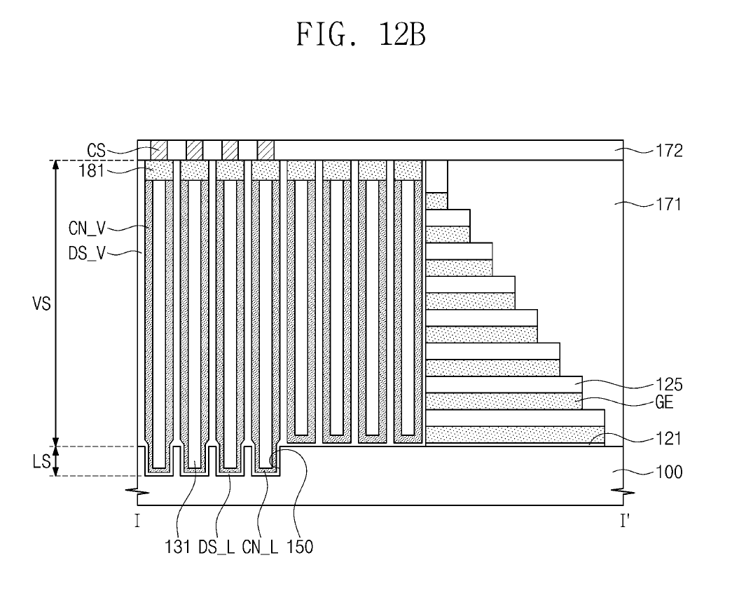

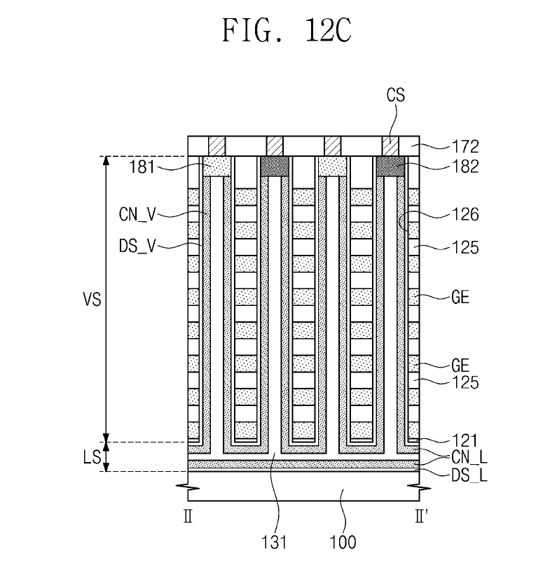

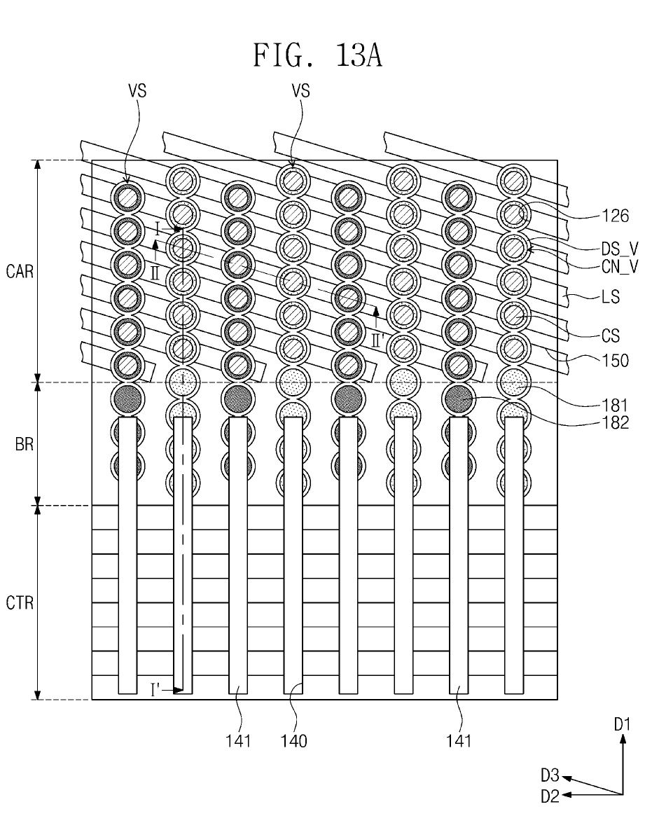

Referring to FIGS. 13A to 13C, separation trenches 140 may be formed that overlap ends of the respective vertical structures VS and extend from the boundary region BR into the contact region CTR to horizontally separate the gate electrodes GE. The formation of the separation trenches 140 may include an anisotropic-etch process. The vertical structures VS and the separation trenches 140 may physically and electrically separate the gate electrodes GE that are adjacent to each other in the second direction D2. Sacrificial insulation patterns 141 may be formed in the separation trenches 140. The separation insulation patterns 141 may include silicon oxide, silicon nitride, or silicon oxynitride. The sacrificial insulation patterns 141 may be formed by an insulation layer that fills the separation trenches 140 and then a planarization process may be performed until a top surface of the second interlayer dielectric layer 172 is exposed.

Referring back to FIGS. 3A to 3C, contacts CT may be formed on the contact regions CTR and connected to the gate electrodes GE. The first interlayer dielectric layer 171 and the second interlayer dielectric layer 172 may be penetrated to form contact holes that expose the pad portions PD of the gate electrodes GE, and then the contact holes may be filled with a conductive material, thereby forming the contacts CT. For example, the cell contacts CT may include a metal, a conductive metal nitride, and a doped semiconductor material. As viewed in a plan view, the contacts CT may be arranged in a zigzag fashion along the second direction D2. Alternatively from the previous description, the contacts CT and the cell studs CS may be formed at the same time.

Conductive lines CL_A and CL_B may be formed to extend in the second direction D2 and connect the cell studs CS that are aligned in the second direction D2 to each other. First conductive lines CL_A may be connected to the vertical channel patterns CN_V of the even-numbered vertical structures VS, and second conductive lines CL_B may be connected to the vertical channel patterns CN_V of the odd-numbered vertical structures VS. Interconnect lines CGL may be disposed on the contacts CT. The conductive lines CL_A and CL_B and the interconnect lines CGL may be formed of a material that includes a metal, a conductive metal nitride, or a doped semiconductor material.

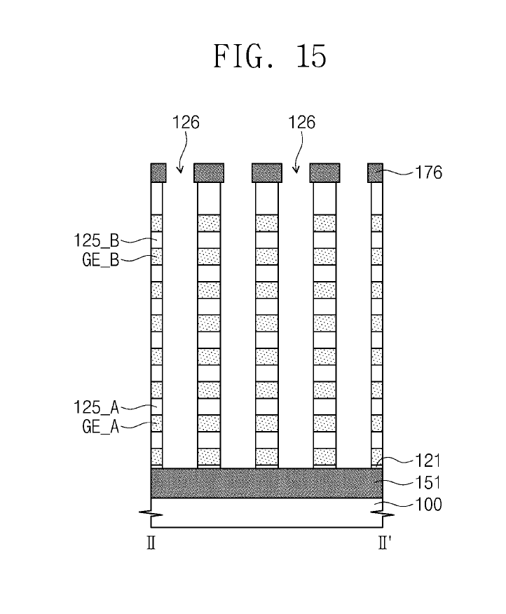

FIG. 15 depicts a cross-sectional view, taken along line II-II′ in FIG. 8A, for explaining a method for fabricating a semiconductor device according to exemplary embodiments of the present inventive concept. For brevity and clarity of the description, an explanation of duplicate components will be omitted.

In an embodiment, the gate electrodes GE may be formed from materials in which each material has different etching characteristics depending on its level from, or height above, the top surface of the substrate 100. For example, during enlargement of the vertical holes 122 described with reference to FIGS. 8A to 8C, first gate electrodes GE_A that are relatively closer to the substrate 100 may have an etch rate that is selected to be greater than the etch rate of second gate electrodes GE_B that are relatively farther away from the substrate 100. For example, four gate electrodes GE that are closest to the substrate 100 may be first gate electrodes GE_A and the remaining four gate electrodes GE may be the second gate electrodes GE_B. Alternatively, the gate electrodes GE may include three or more gate electrodes having different etching characteristics from each other.

Likewise, the insulation patterns 125 may also be formed from materials in which each material has different etching characteristics depending on its level from, or height above, the top surface of the substrate 100. For example, during enlargement of the vertical holes 122 described with reference to FIGS. 8A to 8C, first insulation patterns 125_A that are relatively closer to the substrate 100 may have an etch rate that is selected to be greater than the etch rate of second insulation patterns 125_B that are relatively farther away from the substrate 100.

Due to characteristics of etch process, as a vertical length of the vertical hole 122 becomes larger, a diameter of the vertical hole 122 may become smaller at a lower portion of the vertical hole 122 than at an upper portion of the vertical hole 122. In other words, the vertical hole 122 may have a diameter that increases with increasing distance from, or above, the substrate 100. In an embodiment, layers that are closer to the substrate 100 may be formed of a material having a relatively high etch rate and thus the vertical holes 122 may have enlarged lower portions than upper portions. As a result, the openings 126 may be formed to have sidewalls that are nearer to being vertical than being tapered.

FIG. 16 depicts a block diagram of a semiconductor device according to exemplary embodiments of the present inventive concept.

Referring to FIG. 16, a semiconductor device according to exemplary embodiments of the present inventive concept may include a peripheral logic structure PSS and a cell array structure CSS, and the cell array structure CSS may be stacked on the peripheral logic structure PSS. In other words, the peripheral logic structure PSS and the cell array structure CSS may be vertically overlapped with each other. In one embodiment, the peripheral logic structure PSS may, for example, include the address decoder 20, the read/write circuit 30, the data I/O circuit 40, and the control logic 50 that are described with reference to FIG. 1. The cell array structure CSS may, for example, include a plurality of memory blocks BLK1 to BLKn, each of which is a data erasure unit.

FIG. 17 depicts a block diagram of a semiconductor device according to exemplary embodiments of the present inventive concept. For brevity and clarity of the description, a description of duplicate components will be omitted.

Referring to FIG. 17, a peripheral logic structure PSS and a cell array structure CSS may be sequentially stacked on a semiconductor substrate 11. That is, the peripheral logic structure PSS may be disposed between the semiconductor substrate 11 and the cell array structure CSS. The semiconductor substrate 11 may be a bulk silicon substrate, a silicon on insulator (SOI) substrate, a germanium substrate, a germanium on insulator (GOI) substrate, a silicon-germanium substrate, or an epitaxial layer substrate obtained by performing a selective epitaxial growth (SEG).

The peripheral logic structure PSS may include NMOS and PMOS transistors that are electrically connected to the cell array structure CSS, a resistor a capacitor and/or circuitry and/or components that interface with an external device. The peripheral circuits may be formed on an entire surface of the semiconductor substrate 11. Additionally, the semiconductor substrate 11 may include an n-well region NW that is doped with n-type impurities and a p-well region PW that is doped with p-type impurities. A device isolation layer 21 may be provided to define active regions in the n-well region NW and the p-well region PW.

The peripheral logic structure PSS may include peripheral gate electrodes PG, source and drain impurity regions on opposing sides of each of the peripheral gate electrodes PG, peripheral contact plugs CP, peripheral circuit lines ICL, and a lower interlayer dielectric layer 174 that covers the peripheral circuits. In greater detail, PMOS transistors may be formed on the n-well region NW, and NMOS transistors may be formed on the p-well region PW. The peripheral circuit line ICL may be electrically connected to the peripheral circuits through the peripheral contact plugs CP.

The cell array structure CSS may be identical to a structure of the semiconductor device of FIGS. 3A to 3C except for inclusion of a semiconductor layer 104 in the embodiment of FIG. 17. That is, the semiconductor layer 104 of the present embodiment may take the place of the substrate 100 that is depicted in FIGS. 3A to 3C. In the fabrication process of the cell array structure CSS of the embodiment depicted in FIG. 17, the interconnect trenches 150 described with reference to FIGS. 6A to 6C may be formed in the semiconductor layer 104.

According to exemplary embodiments of the present inventive concept, it may be possible to increase an integration of three-dimensional semiconductor device and to simplify the fabrication process by using a single vertical structure VS that provides two different cell strings CSTR and by forming a peripheral logic structure PSS and a cell array structure CSS that may be sequentially stacked on a semiconductor substrate.

Although the present invention has been described in connection with the embodiment of the present invention illustrated in the accompanying drawings, it is not limited thereto. It will be apparent to those skilled in the art that various substitution, modifications and changes may be thereto without departing from the scope of the claimed subject matter.

What is claimed is:

1. A semiconductor device, comprising:
an electrode structure that includes gate electrodes that are sequentially stacked on a semiconductor layer;
vertical structures that penetrate the electrode structure, extend in a first direction, and are spaced apart from each other in a second direction that crosses the first direction, each of the vertical structures including vertical channel patterns that are arranged in the first direction; and
horizontal structures that extend in a third direction that crosses the first direction below the electrode structure, the horizontal structures including horizontal channel patterns,
wherein each of the horizontal channel patterns is connected to at least three of the vertical channel patterns.

2. The semiconductor device of claim 1, wherein the gate electrodes are separated from each other in the second direction across the vertical structures.

3. The semiconductor device of claim 1, wherein
the first direction and the second direction are substantially parallel to a top surface of the semiconductor layer, and
the third direction is substantially parallel to the top surface of the semiconductor layer and crosses the second direction.

4. The semiconductor device of claim 3, wherein the vertical channel patterns include a first vertical channel and a second vertical channel that are adjacent to each other across the gate electrodes, the first vertical channel and the second vertical channel being spaced apart from each other in the third direction.

5. The semiconductor device of claim 1, wherein each of the vertical structures further comprises a vertical data storage layer, and each of the horizontal structures further comprises a horizontal data storage layer,
wherein the horizontal date storage layer is connected to the vertical data storage layer.

6. The semiconductor device of claim 1, wherein the vertical structures further comprise pads on the vertical channel patterns, the vertical channel patterns comprising:
first vertical channel patterns commonly connected to one of the horizontal channel patterns, and
second vertical channel patterns commonly connected to another horizontal channel pattern that is adjacent to the one horizontal channel patterns,
wherein the pads on the first vertical channel patterns have a conductivity different from that of the pads on the second vertical channel patterns.

7. The semiconductor device of claim 6, wherein the first vertical channel patterns and the second vertical channel patterns are alternately arranged along the third direction.

8. The semiconductor device of claim 1, wherein the semiconductor layer comprises:
a cell array region on which the vertical channel patterns are disposed; and
a contact region on which the gate electrodes are disposed in a stepwise fashion, the contact region being adjacent to the cell array region,
wherein the semiconductor device further comprises separation insulation patterns that extend from each of the vertical structures toward the contact region and separate the gate electrodes in the second direction.

9. The semiconductor device of claim 8, wherein the semiconductor layer further comprises a boundary region between the cell array region and the contact region,
wherein the vertical structures and the separation insulation patterns are overlapped with each other on the boundary region, and the horizontal structures are provided on the cell array region.

10. A semiconductor device, comprising:
an electrode structure that includes a plurality of gate electrodes that are sequentially provided on a semiconductor layer and extend in a first direction; and
vertical structures that separate each of the plurality of gate electrodes in a second direction that crosses the first direction, the vertical structures including data storage layers and channel patterns,
wherein the channel patterns comprise:
vertical channel patterns spaced apart from each other in the first direction across the data storage layers; and
horizontal channel patterns that extend from the vertical channel patterns to below the electrode structure and are connected to the vertical channel patterns of the vertical structures.

11. The semiconductor device of claim 10, wherein each of the horizontal channel patterns is connected to at least three vertical channel patterns.

12. The semiconductor device of claim 10, wherein
the electrode structure and the vertical structures form a plurality of memory cell strings, and
a vertical channel pattern and gate electrodes spaced apart from each other across the vertical channel pattern behave as a pair of different memory cell strings.

13. The semiconductor device of claim 12, wherein a pair of adjacent vertical channel patterns behaves as a channel region of the same memory cell strings, the pair of adjacent vertical channel patterns being connected to one horizontal channel pattern.

14. The semiconductor device of claim 10, wherein
each of the horizontal channel patterns extend in a third direction that crosses the first and second directions, and
the data storage layers extend in the third direction along the horizontal channel patterns.

15. The semiconductor device of claim 10, wherein the semiconductor layer comprises:
a cell array region on which the vertical channel patterns are disposed; and
a contact region on which the gate electrodes are disposed in a stepwise fashion, the contact region being adjacent to the cell array region,
wherein the semiconductor device further comprises separation insulation patterns that extend from each of the vertical structures toward the contact region and separate the gate electrodes in the second direction.

16. A semiconductor device, comprising:
a vertically stacked gate electrode structure comprising a plurality of levels, each level comprising a plurality of gate electrodes, each gate electrode extending in a first direction and being separated from an adjacent gate electrode in a second direction and from an adjacent gate electrode in a vertical direction, the second direction being substantially perpendicular to the first direction, and the vertical direction being substantially perpendicular to the first direction and the second direction;
a plurality of vertical structures that extend in a first direction and separate the gate electrodes in the second direction, each of the vertical structures comprising a plurality of vertical channel patterns that are arranged in the first direction; and
a plurality of horizontal structures that extend in a third direction, the third direction being different from the first direction and different from the second direction, the horizontal structures comprising horizontal channel patterns, and each of the horizontal channel patterns is connected to at least three of the vertical channel patterns.

17. The semiconductor device of claim 16, wherein the vertical channel patterns include a first vertical channel and a second vertical channel that are adjacent to each other across the gate electrodes, the first vertical channel and the second vertical channel being spaced apart from each other in the third direction.

18. The semiconductor device of claim 16, wherein each of the vertical structures further comprises a vertical data storage layer, and
wherein each of the horizontal structures further comprises a horizontal data storage layer that is connected to at least three corresponding vertical data storage layers.

19. The semiconductor device of claim 16, wherein the vertical channel patterns comprise:
first vertical channel patterns commonly connected to corresponding first horizontal channel patterns, and
second vertical channel patterns commonly connected to corresponding second horizontal channel patterns, each second horizontal channel pattern being adjacent to a first horizontal channel pattern,
wherein the vertical structures further comprise a plurality of pads, each pad being on a corresponding vertical channel pattern, and wherein the pads on the first vertical channel patterns have a conductivity that is different from that of the pads on the second vertical channel patterns.

20. The semiconductor device of claim 19, wherein the first vertical channel patterns and the second vertical channel patterns are alternately arranged along the third direction.
